(19) United States
(12) Patent Application Publication
(10) Pub. No.: US 2014/0098509 A1
(43) Pub. Date: Apr. 10, 2014

(54) ELECTRONIC DEVICE AND METHOD FOR MANUFACTURING THEREOF

(71) Applicant: FUJITSU LIMITED, Kawasaki-shi (JP)

(72) Inventors: Atsushi TOMOE, Sapporo (JP); HIROSHI KUBO, Sapporo (JP); Hiroyuki TAKITA, Sapporo (JP)

(73) Assignee: FUJITSU LIMITED, Kawasaki-shi (JP)

(21) Appl. No.: 14/048,788

(22) Filed: Oct. 8, 2013

(30) Foreign Application Priority Data
Oct. 9, 2012 (JP) 2012-223974

(51) Int. Cl. H05K 1/14; H05K 3/36

(52) U.S. Cl. CPC H05K 1/144; H05K 3/368
USPC 361/803; 29/830

(57) ABSTRACT

An electronic device includes a first substrate, a second substrate that is disposed to be superposed over the first substrate, a connector that connects the first substrate to the second substrate, an inter-substrate frame that is disposed between the first substrate and the second substrate and includes a wall portion, and a wall member that is disposed on at least one of the first substrate and the second substrate to be opposed to the wall portion and locks the wall portion of the inter-substrate frame in response to displacement that is generated between the first substrate and the second substrate.

### CROSS-REFERENCE TO RELATED APPLICATION

This application is based upon and claims the benefit of priority of the prior Japanese Patent Application No. 2012-223974, filed on Oct. 9, 2012, the entire contents of which are incorporated herein by reference.

### FIELD

The embodiments discussed herein are related to an electronic device such as a smartphone and a method for manufacturing the electronic device.

### BACKGROUND

The number of mounted components has been increased in a multifunctional mobile terminal device of which a processing speed is raised and a capacity of processing data is increased, for example. A substrate on which such mounted components are mounted is tend to be divided into a plurality of substrates and disposed in a superposed manner. When such plurality of substrates are provided, a stacking connector is used to connect the substrates and perform signal transmission. In this case, the stacking connector fixes the substrates on each other.

Regarding the fixing of substrates, such method has been widely used that a cutout which is formed in a metal plate and a protrusion which is formed on a substrate are engaged with each other to fix the substrate on the metal plate. These techniques are disclosed in Japanese Laid-open Patent Publication No. 2010-028871, for example.

### SUMMARY

According to an aspect of the invention, an electronic device includes a first substrate, a second substrate that is disposed to be superposed over the first substrate, a connector that connects the first substrate to the second substrate, an inter-substrate frame that is disposed between the first substrate and the second substrate and includes a wall portion, and a wall member that is disposed on at least one of the first substrate and the second substrate to be opposed to the wall portion and locks the wall portion of the inter-substrate frame in response to displacement that is generated between the first substrate and the second substrate.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a sectional view illustrating an example of a mobile terminal device according to a first embodiment;

FIG. 2 is a diagram illustrating clearance between a shield cap and a wall portion depicted in FIG. 1 in an enlarging manner;

FIGS. 3A and 3B are diagrams illustrating an example of movement of a substrate;

FIGS. 4A to 4D are diagrams illustrating an example of a method for manufacturing a mobile terminal device;

FIG. 5 is an elevation view illustrating an example of a mobile telephone according to a second embodiment;

FIG. 6 is a diagram illustrating a left side face of the mobile telephone;

FIG. 7 is a perspective view illustrating the mobile telephone which is in a closed state;

FIG. 8 is a diagram illustrating a section taken along a VIII-VIII line of FIG. 7;

FIG. 9 is a diagram illustrating a partial section of an electronic circuit portion of the mobile telephone;

FIG. 10 is an exploded perspective view illustrating a fixed casing portion;

FIG. 11 is an exploded perspective view illustrating the fixed casing portion;

FIGS. 12A and 12B are diagrams illustrating a substrate;

FIGS. 13A and 13B are diagrams illustrating a shield cap;

FIGS. 14A and 14B are diagrams illustrating a substrate;

FIGS. 15A and 15B are diagrams illustrating a shield cap;

FIGS. 16A and 16B are diagrams illustrating an inter-substrate frame;

FIG. 17 is a diagram illustrating the substrate on which the shield cap is disposed;

FIG. 18 is a diagram illustrating the substrate on which the shield cap is disposed;

FIG. 19 is a perspective view illustrating an edge portion of the shield cap depicted in FIG. 18 in an enlarging manner;

FIG. 20 is a diagram illustrating an example of engagement between the substrate and the inter-substrate frame;

FIG. 21 is a diagram illustrating an example of engagement between the substrate and the inter-substrate frame;

FIG. 22 is a diagram illustrating a back face of the mobile telephone;

FIG. 23 is a diagram schematically illustrating a part of a section taken along a XXIII-XXIII line of FIG. 22;

FIG. 24 is a sectional view illustrating an example of a mobile telephone;

FIG. 25 is a diagram illustrating a leg portion and a wall portion in an enlarging manner;

FIGS. 26A and 26B are diagrams illustrating an example of impact absorption;

FIG. 27 is a perspective view illustrating another example of a leg portion;

FIG. 28 is a diagram illustrating another wall portion in an enlarging manner;

FIG. 29 is a diagram illustrating another leg portion of the shield cap in an enlarging manner;

FIG. 30 is a diagram illustrating a mobile telephone according to a comparison example;

FIG. 31 is a sectional view illustrating an example of a mobile terminal device;

FIG. 32 is a diagram illustrating a substrate; and

FIG. 33 is a sectional view illustrating an example of a mobile terminal device.

### DESCRIPTION OF EMBODIMENTS

Conventionally, a room (backlash) for adhesion is provided between a casing and a substrate in a case in which a plurality of substrates are disposed in the casing. This backlash enables movement of the substrates which are disposed. Therefore, a gap is generated among the superposed substrates in a case of reception of an impact caused by dropping or the like. This gap acts stress on a stacking connector which connects the substrates to each other and damages soldering parts of the connector.

It is possible to raise fixing strength by using fixing screws and the like for fixing of substrates, but it is difficult to use many fixing screws due to reduction in assembling man hour, in size, and in weight of a mobile terminal device. Therefore, claws or the like have to be formed on a metal frame so as to fix substrates by these claws as disclosed in Japanese Laid-open Patent Publication No. 2010-028871 and the like. Such fixing configuration has low resistance against an impact, having difficulty in avoiding generation of a gap among substrates.

### First Embodiment

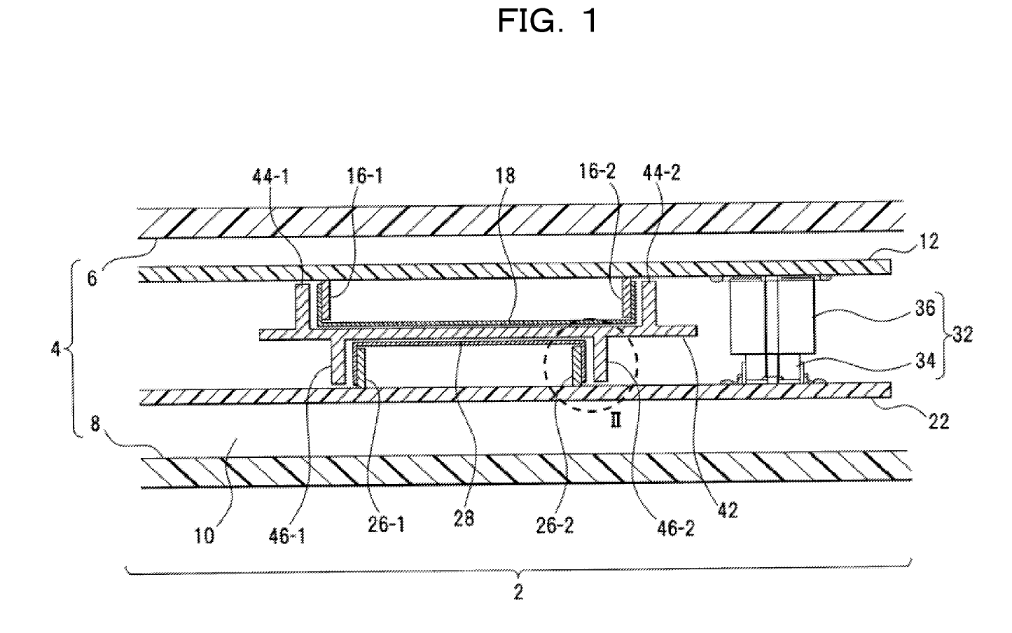

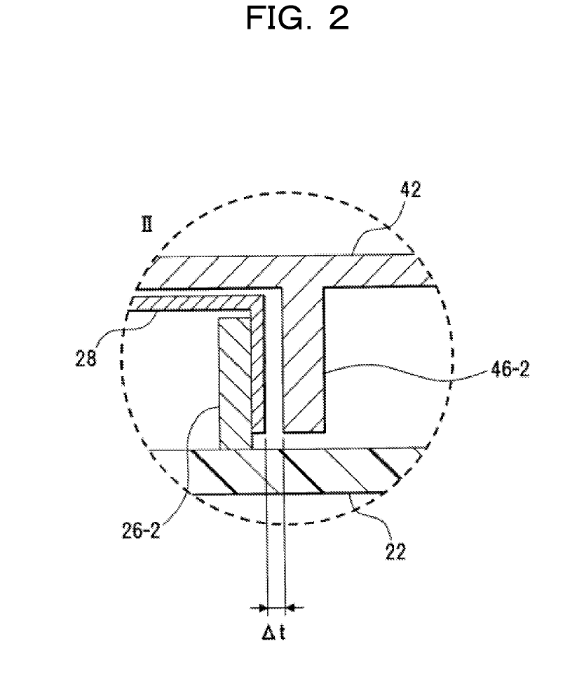

FIG. 1 is a sectional view of a part of a mobile terminal device according to a first embodiment. FIG. 2 illustrates clearance between a shield cap and a wall portion in an enlarging manner. FIG. 2 illustrates a range II depicted in FIG. 1, in an enlarging manner.

This mobile terminal device 2 is an example of an electronic device and a method for manufacturing the electronic device according to embodiments of the present disclosure. The mobile terminal device 2 depicted in FIG. 1 includes a case 4. This case 4 is an example of a casing. This case 4 includes an upper case 6 and a lower case 8. In a space portion 10 which is formed by the upper case 6 and the lower case 8, a plurality of substrates 12 and 22 are disposed. The substrate 12 is an example of a first substrate. Further, the substrate 22 is an example of a second example.

The substrates 12 and 22 are disposed in parallel with each other in an opposed manner. On an opposed face portion, which is opposed to the substrate 22, of the substrate 12 which is disposed on the upper case 6 side, a female connector portion 36 of a connector 32 is disposed and frame members 16-1 and 16-2 are disposed. A plurality of electronic components, which are not depicted in the drawing, are mounted on this substrate 12. The connector 32 is a stacking connector, for example.

Further, on an opposed face portion, which is opposed to the substrate 12, of the substrate 22 which is disposed on the lower case 8 side, a male connector portion 34 of the connector 32 is disposed and frame members 26-1 and 26-2 are disposed. A plurality of electronic components, which are not depicted in the drawing, are mounted on this substrate 22.

The frame members 16-1 and 16-2 are examples of a wall member. The frame members 16-1 and 16-2 are disposed on the substrate 12 to form walls. The frame members 16-1 and 16-2 are covered by a shield cap 18. The shield cap 18 is an example of a shield member and is made of a metal material, for example. The shield cap 18 is held on the frame members 16-1 and 16-2 by elasticity of this metal material. In a similar manner, the frame members 26-1 and 26-2 are examples of a wall member. The frame members 26-1 and 26-2 are disposed on the substrate 22 to form walls. The frame members 26-1 and 26-2 are covered by a shield cap 28. The shield cap 28 is an example of a shield member and is made of a metal material, for example. The shield cap 28 is held on the frame members 26-1 and 26-2 by elasticity of this metal material.

An inter-substrate frame 42 is disposed between the substrates 12 and 22. That is, this inter-substrate frame 42 is interposed between the shield caps 18 and 28. Wall portions 44-1 and 44-2 are formed on the inter-substrate frame 42 in a manner to sandwich the shield cap 18. The wall portion 44-1 faces a lateral face of the shield cap 18 and the frame member 16-1 and the wall portion 44-2 faces a lateral face of the shield cap 18 and the frame member 16-2. Further, wall portions 46-1 and 46-2 are formed on the inter-substrate frame 42 in a manner to sandwich the shield cap 28. The wall portion 46-1 faces a lateral face of the shield cap 28 and the frame member 26-1 and the wall portion 46-2 faces a lateral face of the shield cap 28 and the frame member 26-2.

To the female connector portion 36, the male connector portion 34 is attached. This connector 32 connects the substrate 12 and the substrate 22 with each other. That is, the connector 32 is used for connection between an electronic circuit on the substrate 12 and an electronic circuit on the substrate 22 and is used for mechanical connection between the substrates 12 and 22.

<Motion in Impact Reception>

(1) Case in which Impact is Applied to Substrate 12

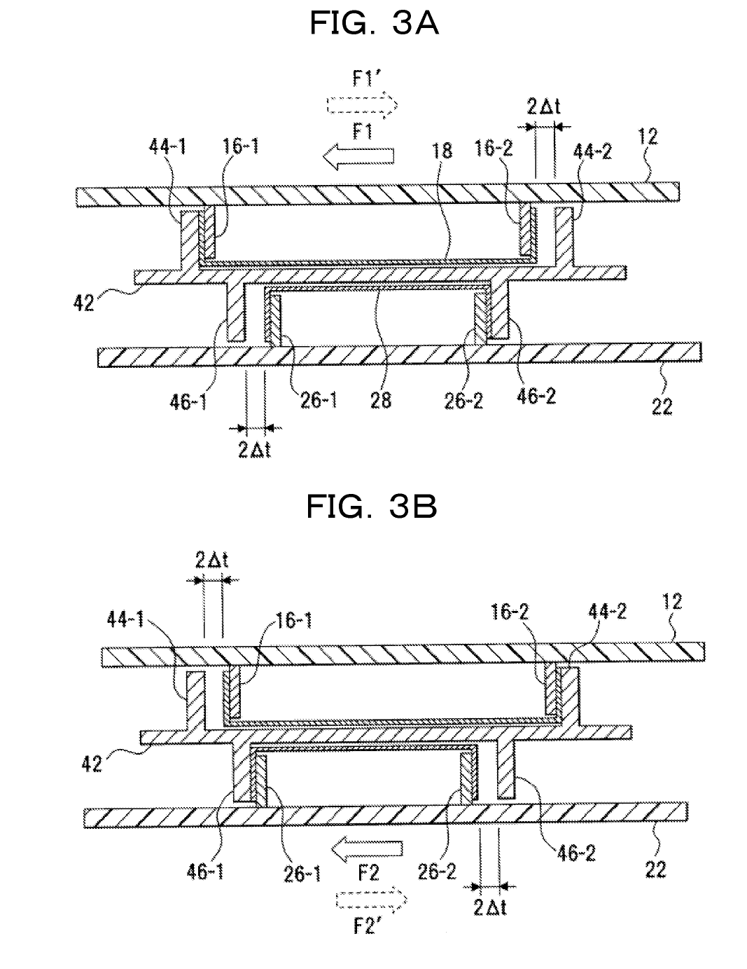

When an impact is applied to the substrate 12, displacement is generated between the substrate 12 and the substrate 22. In this case, the frame members 16-1, 16-2, 26-1, and 26-2 lock the wall portions 44-1, 44-2, 46-1, and 46-2 of the inter-substrate frame 42 in response to the generated displacement. For example, when an impact F1 is applied to the substrate 12 as depicted in FIG. 3A, the substrate 12 moves toward the direction of the impact F1. Due to this movement, the shield cap 18 and the frame member 16-1 collide against the wall portion 44-1 of the inter-substrate frame 42, to which the shield cap 18 and the frame member 16-1 are opposed, to lock the wall portion 44-1 and move the inter-substrate frame 42 toward the direction of the impact F1. Accordingly, the wall portion 46-2 of the inter-substrate frame 42 which has moved collides against the lateral face, which is on the substrate 22 side, of the shield cap 28 and the frame member 26-2. As a result, the frame member 26-2 locks the wall portion 46-2. Clearance between the shield cap 28 and the wall portion 46-2 of the inter-substrate frame 42 is denoted as Δt (FIG. 2). In a similar manner, clearance between the shield cap 18 and each of the wall portions 44-1 and 44-2 of the inter-substrate frame 42 is denoted as Δt, and clearance between the shield cap 28 and the wall portion 46-1 of the inter-substrate frame 42 is denoted as Δt. A stroke of the substrate 12 is twice as much as Δt (2×Δt). Thus, the inter-substrate frame 42 is moved in the direction of the impact F1 due to the movement of the substrate 12, but the impact F1 is dispersed and absorbed by collision and lock among the wall portion 44-1, the lateral face of the shield cap 18, and the frame member 16-1, and among the wall portion 46-2, the lateral face of the shield cap 28, and the frame member 26-2. As a result, the impact, which is present between the substrates 12 and 22, with respect to the connector 32 is reduced, being able to suppress stress applied to a connecting portion of the connector 32. Here, actual clearance Δt is small, but the clearance is illustrated in an enlarged manner so as to simplify the description.

When an impact F1′ is applied to the substrate 12, motion opposite to that of the case in which the impact F1 is applied is generated. In this case, the impact F1′ is dispersed and absorbed by collision and lock among the wall portion 44-2, the lateral face of the shield cap 18, and the frame member 16-2, and among the wall portion 46-1, the lateral face of the shield cap 28, and the frame member 26-1. As a result, the impact, which is present between the substrates 12 and 22, with respect to the connector 32 is reduced, being able to suppress stress applied to the connecting portion of the connector 32.

(2) Case in which Impact is Applied to Substrate 22

When an impact is applied to the substrate 22, displacement is generated between the substrate 12 and the substrate 22. In this case, the frame members 16-1, 16-2, 26-1, and 26-2 lock the wall portions 44-1, 44-2, 46-1, and 46-2 of the inter-substrate frame 42 in response to the generated displacement. For example, when an impact F2 is applied to the substrate 22 as depicted in FIG. 3B, the substrate 22 moves toward the direction of the impact F2. Due to this movement, the shield cap 28 and the frame member 26-1 collide against the wall portion 46-1 of the inter-substrate frame 42, to which the shield cap 28 and the frame member 26-1 are opposed, to lock the wall portion 46-1 and move the inter-substrate frame 42 toward the direction of the impact F2. Accordingly, the wall portion 44-2 of the inter-substrate frame 42 which has moved collides against the lateral face, which is on the substrate 12 side, of the shield cap 18 and the frame member 16-2. As a result, the frame member 16-2 locks the wall portion 44-2. Clearance between the shield cap 18 and each of the wall portions 44-1 and 44-2 of the inter-substrate frame 42 is denoted as Δt, and clearance between the shield cap 28 and each of the wall portions 46-1 and 46-2 of the inter-substrate frame 42 is denoted as Δt in a similar manner. A stroke of the inter-substrate frame 42 is twice as much as Δt (2×Δt). Thus, the inter-substrate frame 42 is moved in the direction of the impact F2 by the movement of the substrate 22, but the impact F2 is dispersed and absorbed due to collision and lock among the wall portion 44-2, the lateral face of the shield cap 18, and the frame member 16-2, and among the wall portion 46-1, the lateral face of the shield cap 28, and the frame member 26-1. As a result, the impact, which is present between the substrates 12 and 22, with respect to the connector 32 is reduced, being able to suppress stress applied to the connecting portion of the connector 32. Here, actual clearance Δt is small, but the clearance is illustrated in an enlarged manner so as to simplify the description.

When an impact F2′ is applied to the substrate 22, motion opposite to that of the case in which the impact F2 is applied is generated. In this case, the impact F2′ is dispersed and absorbed by collision and lock among the wall portion 44-1, the lateral face of the shield cap 18, and the frame member 16-1, and among the wall portion 46-2, the lateral face of the shield cap 28, and the frame member 26-2. As a result, the impact, which is present between the substrates 12 and 22, with respect to the connector 32 is reduced, being able to suppress stress applied to the connecting portion of the connector 32.

<Method for Manufacturing Mobile Terminal Device 2>

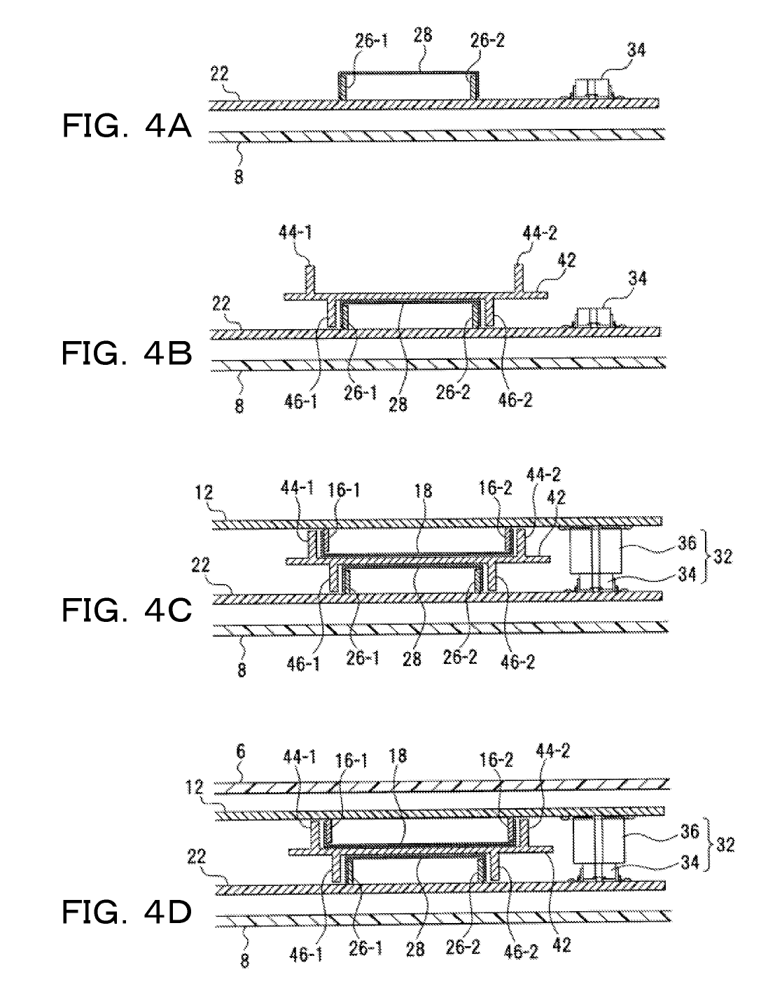

FIG. 4A to FIG. 4D illustrate an example of a method for manufacturing a mobile terminal device.

This manufacturing process includes an attaching process on the substrate 22 side (FIG. 4A), an attaching process of the inter-substrate frame 42 (FIG. 4B), an attaching process of the substrate 12 and a coupling process of a connector (FIG. 4C), and an attaching process of the upper case 6 (FIG. 4D).

As depicted in FIG. 4A, the male connector portion 34 and the frame members 26-1 and 26-2 are disposed to be attached on the opposed face portion, which is opposed to the substrate 12, of the substrate 22. Further, the shield cap 28 is held at the frame members 26-1 and 26-2. This substrate 22 is disposed to be attached on the lower case 8.

Subsequently, as depicted in FIG. 4B, the wall portions 44-1 and 44-2 with respect to the shield cap 18 and the wall portions 46-1 and 46-2 with respect to the shield cap 28 are formed on the inter-substrate frame 42. This inter-substrate frame 42 is disposed to be attached on the substrate 22. Due to the disposition of the inter-substrate frame 42, the wall portions 46-1 and 46-2 sandwich the shield cap 28.

Then, as depicted in FIG. 4C, the female connector portion 36 and the frame members 16-1 and 16-2 are disposed to be attached on the opposed face portion, which is opposed to the substrate 22, of the substrate 12. Further, the shield cap 18 is held at the frame members 16-1 and 16-2. This substrate 12 is disposed to be attached on the inter-substrate frame 42. Due to the disposition of the inter-substrate frame 42, the wall portions 44-1 and 44-2 sandwich the shield cap 18. Further, due to the disposition of the substrate 12, the male connector portion 34 is attached to the female connector portion 36 and thus the substrate 12 and the substrate 22 are connected with each other. Thus, the inter-substrate frame 42 is interposed between the substrates 12 and 22.

Subsequently, as depicted in FIG. 4D, the upper case 6 is attached to the lower case.

Formation of the wall portions 44-1 and 44-2 on the inter-substrate frame 42 facilitates position setting of the substrate 12 and the inter-substrate frame 42. In the same fashion, formation of the wall portions 46-1 and 46-2 facilitates position setting of the substrate 22 and the inter-substrate frame 42. Thus, the wall portions 44-1, 44-2, 46-1, and 46-2 facilitate assembling of the substrates 12 and 22 and the inter-substrate frame 42.

Regarding this manufacturing process, the manufacturing example started from the lower case 8 side is illustrated in FIG. 4A to FIG. 4D, but manufacturing may be started from the upper case 6 side or a stored part of a case such as the substrates 12 and 22 and the inter-substrate frame 42.

### Second Embodiment

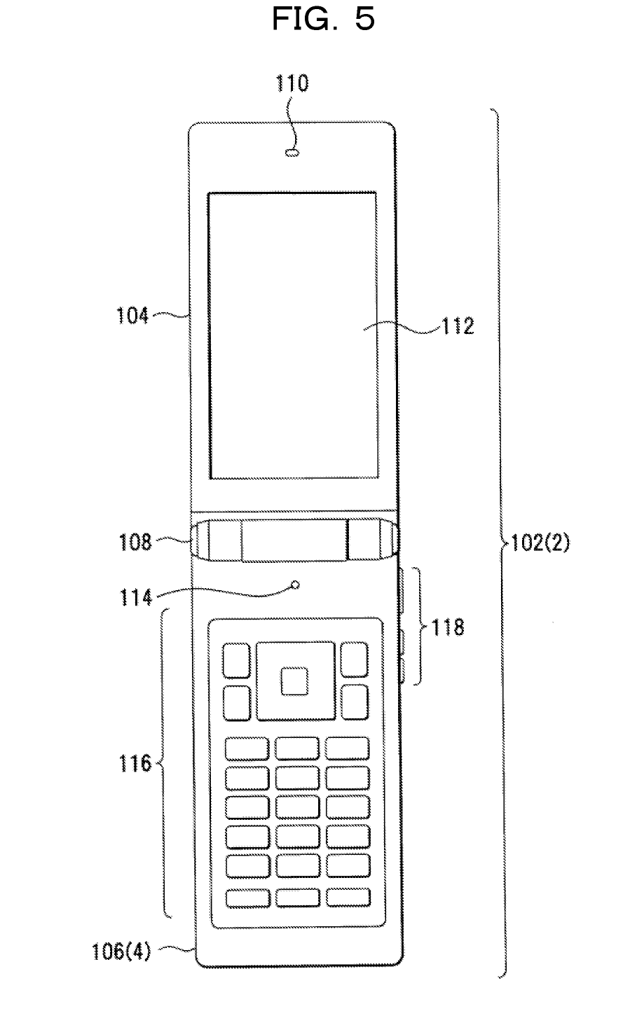

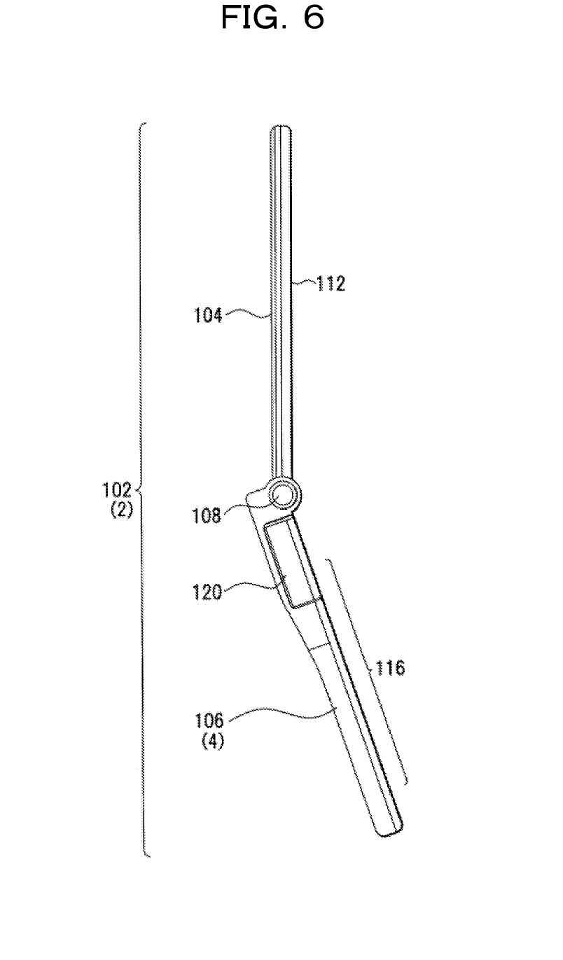

FIG. 5 illustrates a front face of a mobile telephone according to a second embodiment. FIG. 6 illustrates a lateral face of the mobile telephone.

This mobile telephone 102 is an example of the mobile terminal device and the electronic device according to embodiments of the present disclosure. In the mobile telephone 102 depicted in FIG. 5, a movable casing portion 104 and a fixed casing portion 106 are coupled via a hinge portion 108. The hinge portion 108 enables opening/closing of the movable casing portion 104 with respect to the fixed casing portion 106.

A speaker 110 and a display 112 are disposed on the movable casing portion 104. The speaker 110 is an example of a unit which outputs sounds. The display 112 is an example of a unit which displays display information such as letters and graphics. The display 112 is a liquid crystal display, a plasma display, or an organic electroluminescence (EL) display, for example.

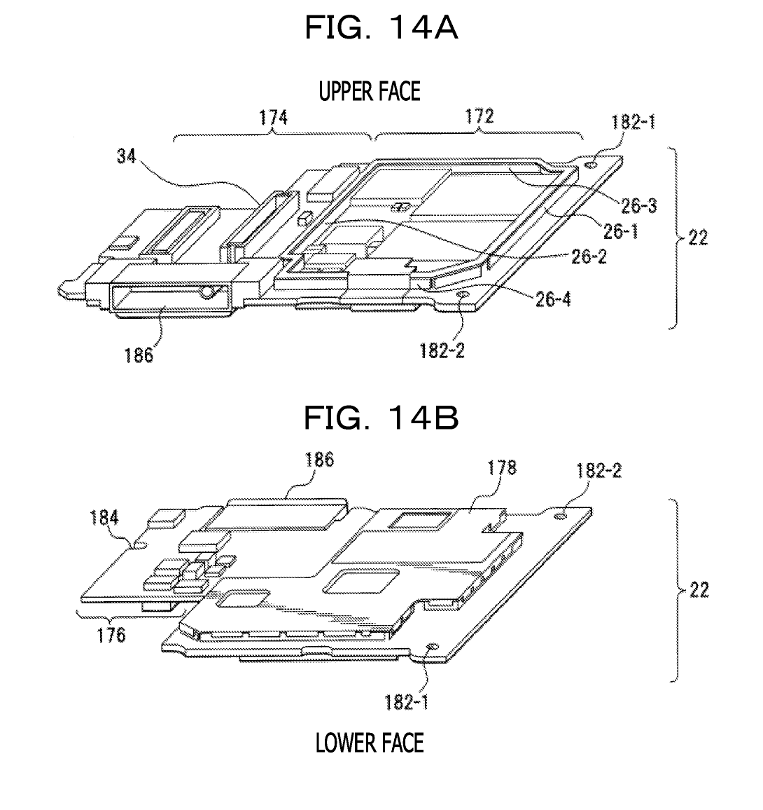

The fixed casing portion 106 is an example of the case 4 and a casing. On the front face of the fixed casing portion 106, a microphone 114 and operation keys 116 are arranged. On a right side face of the fixed casing portion 106, operation keys 118 are arranged. On a left side face of the fixed casing portion 106, a protection cover 120 of a connecting port 186 (FIG. 14A) is disposed. The microphone 114 is an example of a unit which inputs sounds into the mobile telephone 102. The operation keys 116 and 118 are examples of units which receive information input.

<Configuration of Inside of Fixed Casing Portion>

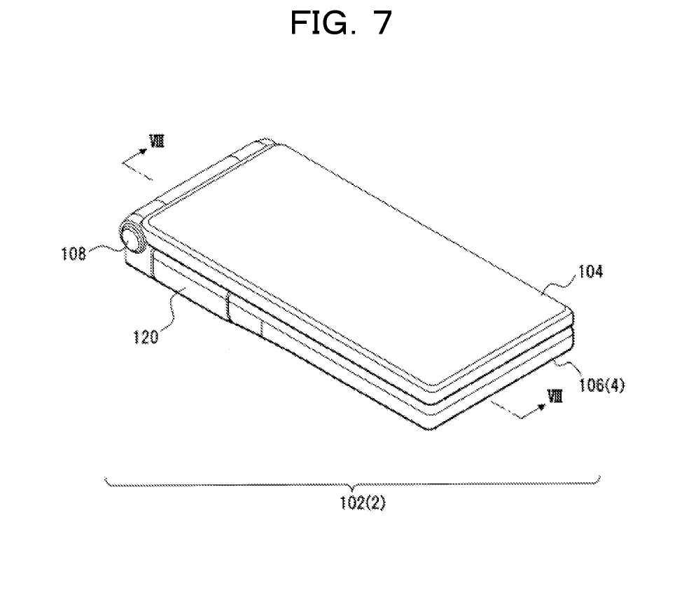

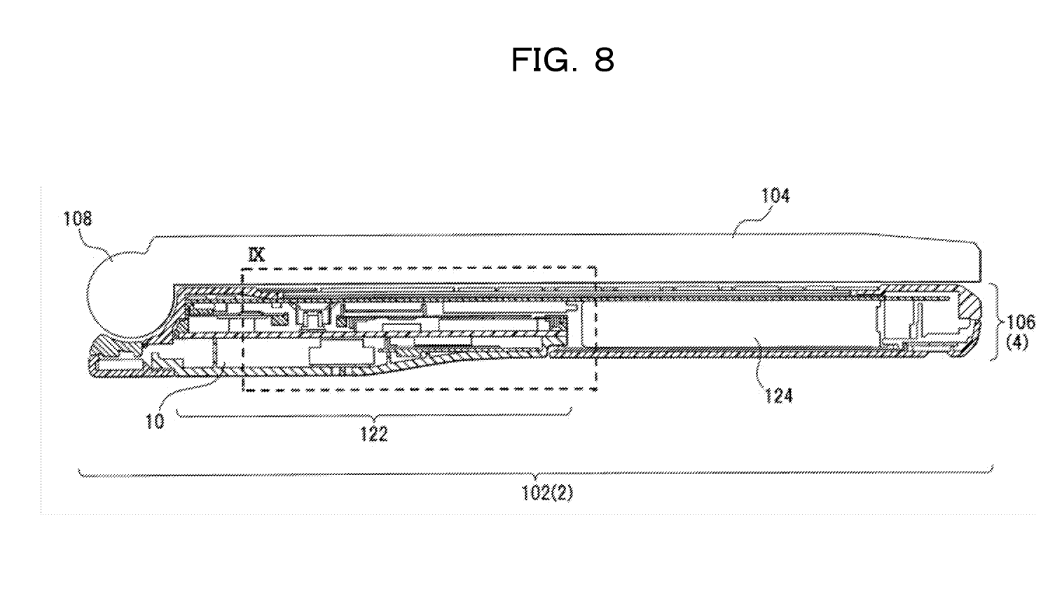

FIG. 7 illustrates a mobile telephone which is in a closed state. FIG. 8 is a sectional view, which is taken along a VIII-VIII line of FIG. 7, of a part of the mobile telephone depicted in FIG. 7. Regarding the movable casing portion 104 and the hinge portion 108, only outlines are depicted and other parts are omitted.

The space portion 10 is formed by the fixed casing portion 106 depicted in FIG. 8. On the hinge portion 108 side of this space portion 10, an electronic circuit portion 122 of the mobile telephone 102 is disposed. Further, in the space portion 10 distant from the hinge portion 108, a battery 124 is disposed. This battery 124 is an example of a unit which provides electricity to the mobile telephone 102.

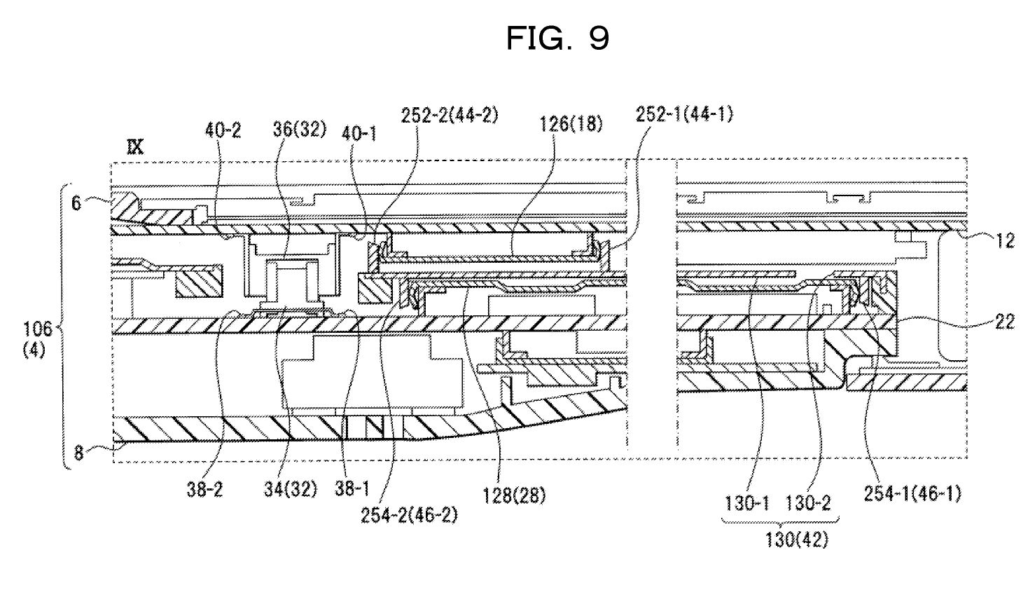

FIG. 9 illustrates a partial section of the electronic circuit portion of the mobile telephone. FIG. 9 illustrates a range IX depicted in FIG. 8 while omitting a part of the range in an enlarging fashion. The fixed casing portion 106 depicted in FIG. 9 includes the upper case 6 and the lower case 8. The substrates 12 and 22 are disposed in the space portion 10. The substrate 12 is an example of the first substrate. This substrate 12 is a front substrate, for example. Further, the substrate 22 is an example of the second substrate. This substrate 22 is a main substrate, for example. The substrates 12 and 22 are composed of an insulation synthetic resin plate, for example.

On the opposed face portion, which is opposed to the substrate 22, of the substrate 12 which is disposed on the upper case 6 side, the female connector portion 36 of the connector 32 is disposed by solders 40-1 and 40-2 and the shield cap 126 is attached. The connector 32 is a stacking connector, for example.

Further, on the opposed face portion, which is opposed to the substrate 12, of the substrate 22 which is disposed on the lower case 8 side, the male connector portion 34 of the connector 32 is disposed by solders 38-1 and 38-2 and the shield cap 128 is attached.

An inter-substrate frame 130 is interposed between the substrates 12 and 22. That is, this inter-substrate frame 130 is interposed between the shield caps 126 and 128. On this inter-substrate frame 130, wall portions 252-1 and 252-2 are formed in a manner to sandwich the shield cap 126. The wall portions 252-1 and 252-2 respectively face lateral faces of the shield cap 126. Further, on the inter-substrate frame 130, wall portions 254-1 and 254-2 are formed in a manner to sandwich the shield cap 128. The wall portions 254-1 and 254-2 respectively face lateral faces of the shield cap 128.

To the female connector portion 36, the male connector portion 34 is attached. This connector 32 connects the substrate 12 and the substrate 22 with each other. That is, the connector 32 is used for connection between the electronic circuit on the substrate 12 and the electronic circuit of the substrate 22 and is used for mechanical connection between the substrates 12 and 22. Here, the male connector portion 34 and the female connector portion 36 may be respectively fixed on the substrates 22 and 12.

<Configuration of Inside of Fixed Casing Portion>

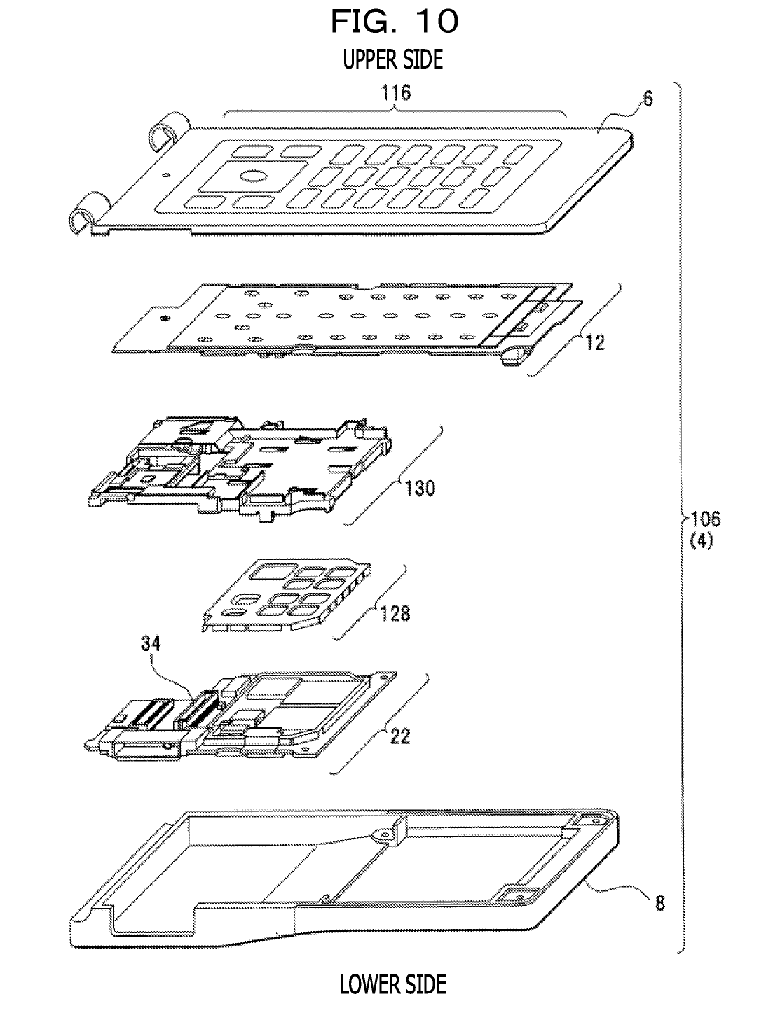

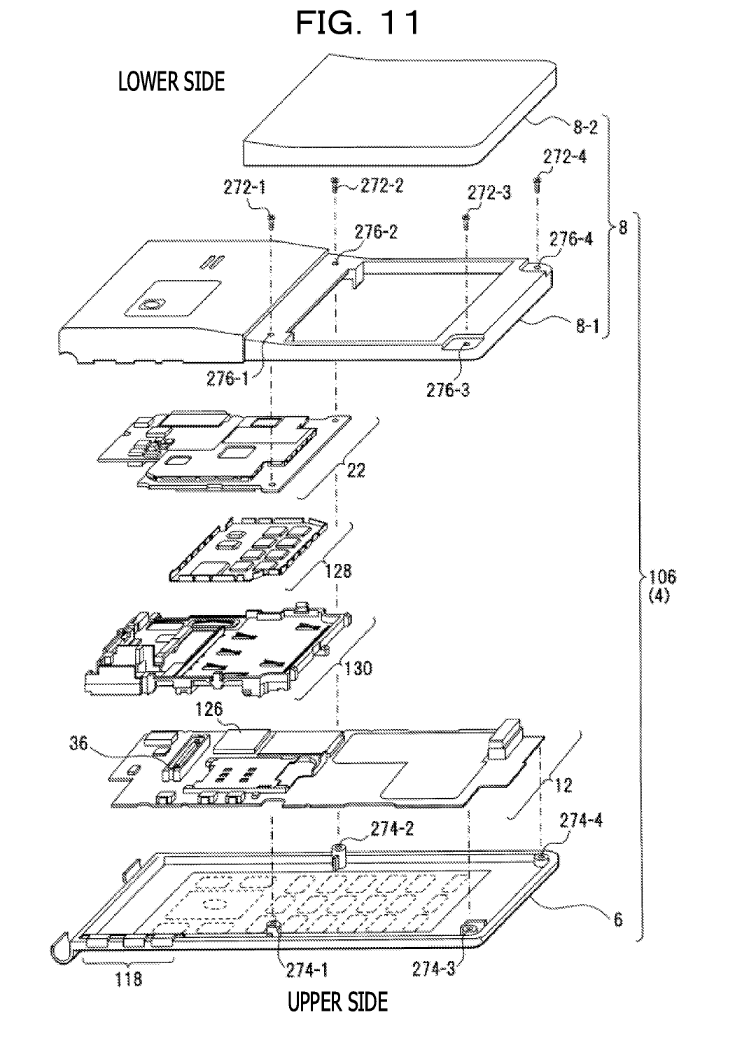

FIG. 10 and FIG. 11 are exploded perspective views of the fixed casing portion. FIG. 10 illustrates the fixed casing portion viewed diagonally from the front. FIG. 11 illustrates the fixed casing portion viewed diagonally from the back. Here, a front face side on which the operation keys 116 are disposed is assumed to be an upper side and a back face side is assumed to be a lower side. FIG. 10 illustrates upper faces of respective members and FIG. 11 illustrates lower faces of respective members.

Between the upper case 6 and the lower case 8, the substrate 12, the inter-substrate frame 130, the shield cap 128, and the substrate 22 are disposed. Further, on the lower face of the substrate 12, the shield cap 126 (FIG. 11) is disposed.

The upper case 6 includes screw receiving portions 274-1, 274-2, 274-3, and 274-4. A case body portion 8-1 of the lower case 8 includes through holes 276-1, 276-2, 276-3, and 276-4 which respectively correspond to the screw receiving portions 274-1, 274-2, 274-3, and 274-4. The lower case 8 is screwed to the upper case 6 by fixing screws 272-1, 272-2, 272-3, and 272-4. The fixing screws 272-1, 272-2, 272-3, and 272-4 are examples of fixing units. The fixing may be fixing by adhesion.

On the case body portion 8-1, a cover 8-2 of the lower case 8 is superposed. When the cover 8-2 is superposed, an opening of the case body portion 8-1 is covered and at the same time, the through holes 276-1, 276-2, 276-3, and 276-4 are covered.

<Configuration of Substrate 12>

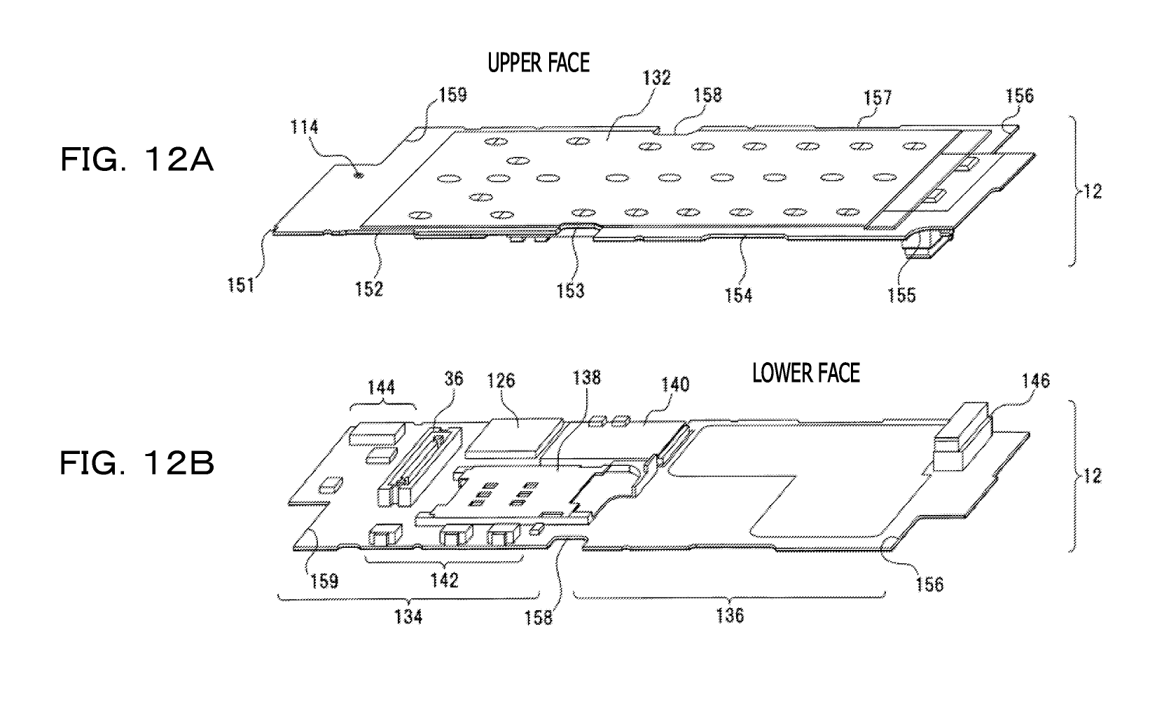

FIG. 12A illustrates an upper face of a substrate. On the upper face of the substrate 12 depicted in FIG. 12A, the microphone 114 and a key detection device 132 are disposed. The key detection device 132 is adjacent to the operation keys 116 (FIG. 10). The key detection device 132 is an example of a unit which detects an operation of the operation keys 116 and detects press of the operation keys, for example.

FIG. 12B illustrates a lower face of a substrate. The lower face of the substrate 12 depicted in FIG. 12B includes an electronic member arrangement region 134 and a battery arrangement region 136.

In the electronic member arrangement region 134, the shield cap 126, the female connector portion 36, access devices 138 and 140, a key detection device 142, and a plurality of electronic members 144 are disposed. The key detection device 142 is an example of a unit which detects an operation of the operation keys 118 and detects press of the operation keys 118, for example.

The shield cap 126 is an example of a unit which shields electromagnetic waves. This shield cap 126 covers and protects the electronic members which are disposed thereinside.

The access devices 138 and 140 are examples of a unit which accesses information. The access devices 138 and 140 house an information storage card such as a secure digital (SD) card and a universal subscriber identity module (USIM) card. The access devices 138 and 140 read stored information from the information storage card which is housed or write information in the information storage card. Namely, the access devices 138 and 140 function as information storage media.

On the battery arrangement region 136, the battery 124 (FIG. 8) is mounted. Further, a power source connection terminal 146 is disposed near the battery 124. The power source connection terminal 146 receives power from the battery 124 and provides the power to the mobile telephone 102.

On the circumference of the substrate 12, a plurality of concave portions 151, 152, . . . , 159 are formed. These concave portions 151, 152, . . . , 159 are used for avoidance of interference of members or position setting of the substrate 12.

This substrate 12 mounts the battery 124 and the information storage card, thus functioning as a power source and an information storage source. Further, the substrate 12 includes the microphone 114 and the key detection devices 132 and 142, exerting an information inputting function.

<Configuration of Shield Cap 126>

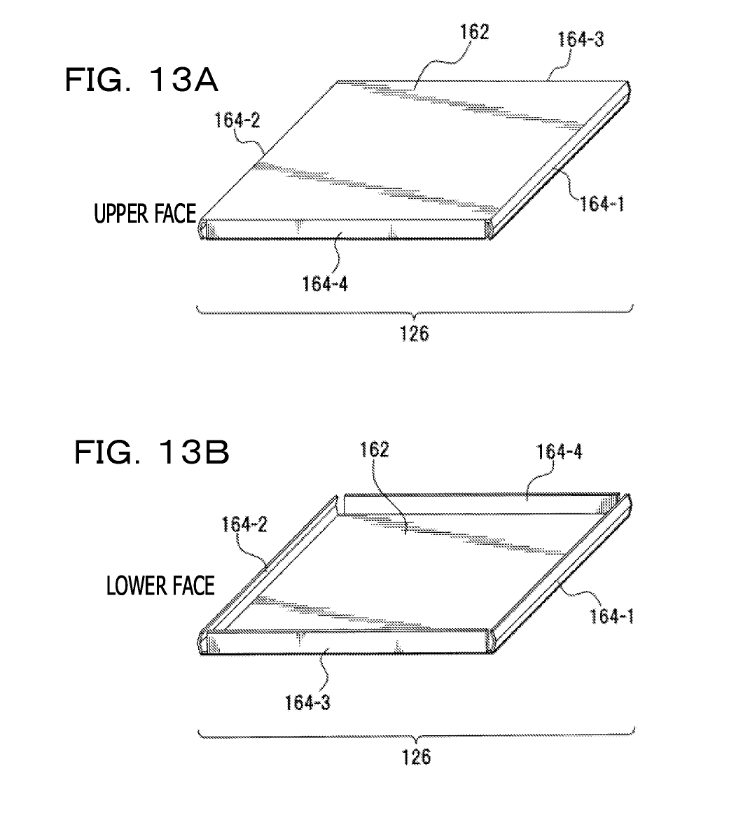

FIG. 13A illustrates an upper face of a shield cap. FIG. 13B illustrates a lower face of the shield cap. The shield cap 126 includes a lid portion 162 and leg portions 164-1, 164-2, 164-3, and 164-4. The leg portions 164-1, 164-2, 164-3, and 164-4 are formed on a circumference of the lid portion 162 so as to constitute lateral portions of the shield cap 126. These leg portions 164-1, 164-2, 164-3, and 164-4 are formed by bending edge portions of the shield cap 126, for example. The shield cap 126 has a concave shape.

The leg portions 164-1 and 164-2 are bent at the central parts thereof. These bends form springs and thus the leg portions 164-1 and 164-2 constitute elastic members having elasticity. Here, the central part may be a central point or a central region. The leg portions 164-1 and 164-2 are examples of an elastic member.

The shield cap 126 is made of a metal material such as a metal plate, for example. A shield metal plate is used for the shield cap 126, for example. The lid portion 162 covers the upper portions of the electronic members and the leg portions 164-1, 164-2, 164-3, and 164-4 cover the periphery of the electronic members. Accordingly, the shield cap 126 shields electromagnetic waves between the included electronic members and the outside so as to protect the electronic members. Further, the shield cap 126 is connected with the ground of the substrate 12 to enlarge an area of the ground of the substrate 12. Thus, the shield cap 126 strengthens the ground of the substrate 12 and enhances stability of the ground.

<Configuration of Substrate 22>

FIG. 14A illustrates an upper face of the substrate 22. On this upper face, a plurality of electronic members 172 and 174 and the male connector portion 34 are disposed. Further, on the periphery of the plurality of electronic members 172, the frame members 26-1, 26-2, 26-3, and 26-4 are disposed. The frame members 26-1, 26-2, 26-3, and 26-4 are made of a metal material such as a metal plate, for example, and are connected to the ground of the substrate 22. The frame members 26-1 and 26-2 are same as those of the first embodiment.

FIG. 14B illustrates a lower face of the substrate 22. On the lower face of the substrate 22, a plurality of electronic members 176 and a shield cap 178 are disposed. This shield cap 178 is an example of a shield member. Electronic members are disposed between this shield cap 178 and the substrate 22. This shield cap 178 is made of a metal material such as a metal plate, for example. This shield cap 178 is connected with the ground of the substrate 22.

On the substrate 22, through holes 182-1 and 182-2 are formed. These through holes 182-1 and 182-2 are formed close to corners, which are adjacent to each other, of the substrate 22. Fixing screws 272-1 and 272-2 are inserted through these through holes 182-1 and 182-2. These through holes 182-1 and 182-2 are used for disposing the substrate 22 on the fixed casing portion 106. Further, the substrate 22 has a cutout portion 184 on an edge portion thereof. This cutout portion 184 is used for joining between the substrate 22 and the inter-substrate frame 130.

A connection port 186 is disposed on a lateral face of the substrate 22 and is used for connection of an AC adapter and communication connection with external devices.

<Configuration of Shield Cap 128>

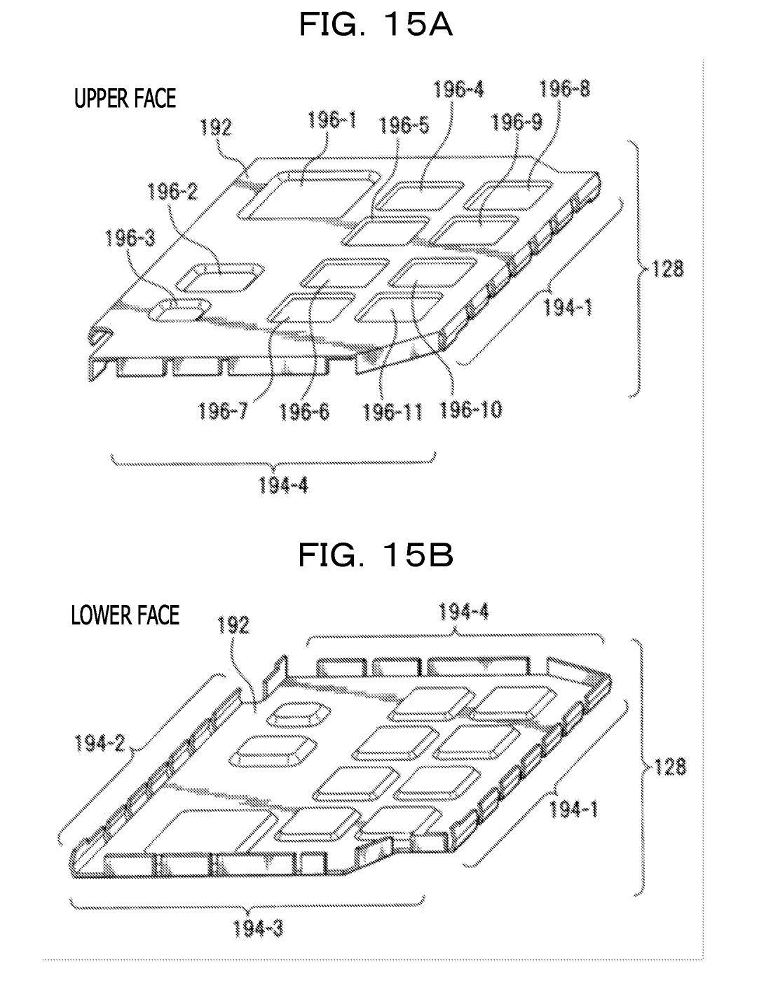

FIG. 15A illustrates an upper face of a shield cap, and FIG. 15B illustrates a lower face of the shield cap. The shield cap 128 depicted in FIG. 15A includes a lid portion 192 and leg portions 194-1, 194-2, 194-3, and 194-4. The leg portions 194-1, 194-2, 194-3, and 194-4 are formed on a circumference of the lid portion 192 so as to constitute lateral portions of the shield cap 128. These leg portions 194-1, 194-2, 194-3, and 194-4 are formed by bending edge portions of the shield cap 128, for example. The shield cap 128 has a concave shape.

The leg portions 194-1 and 194-2 are bent at the central parts thereof. These bends form springs and thus the leg portions 194-1 and 194-2 constitute elastic members having elasticity. The leg portions 194-1 and 194-2 are examples of an elastic member.

On the lid portion 192 of the shield cap 128, a plurality of concave portions 196-1, 196-2, . . . , 196-11 are formed. Unevenness formed by these concave portions 196-1, 196-2, . . . , 196-11 raises strength of the shield cap 128.

The shield cap 128 is made of a metal material such as a metal plate, for example. A shield metal plate is used for the shield cap 128, for example. The lid portion 192 covers the upper portions of a plurality of electronic members 172 (FIG. 14A) and the leg portions 194-1, 194-2, 194-3, and 194-4 cover the periphery of the electronic members 172. Accordingly, the shield cap 128 shields electromagnetic waves between the electronic members 172 and the outside so as to protect the electronic members 172. The shield cap 128 is connected with the ground of the substrate 22 to enlarge an area of the ground of the substrate 22. Thus, the shield cap 128 strengthens the ground of the substrate 22 and enhances stability of the ground.

<Configuration of Inter-Substrate Frame>

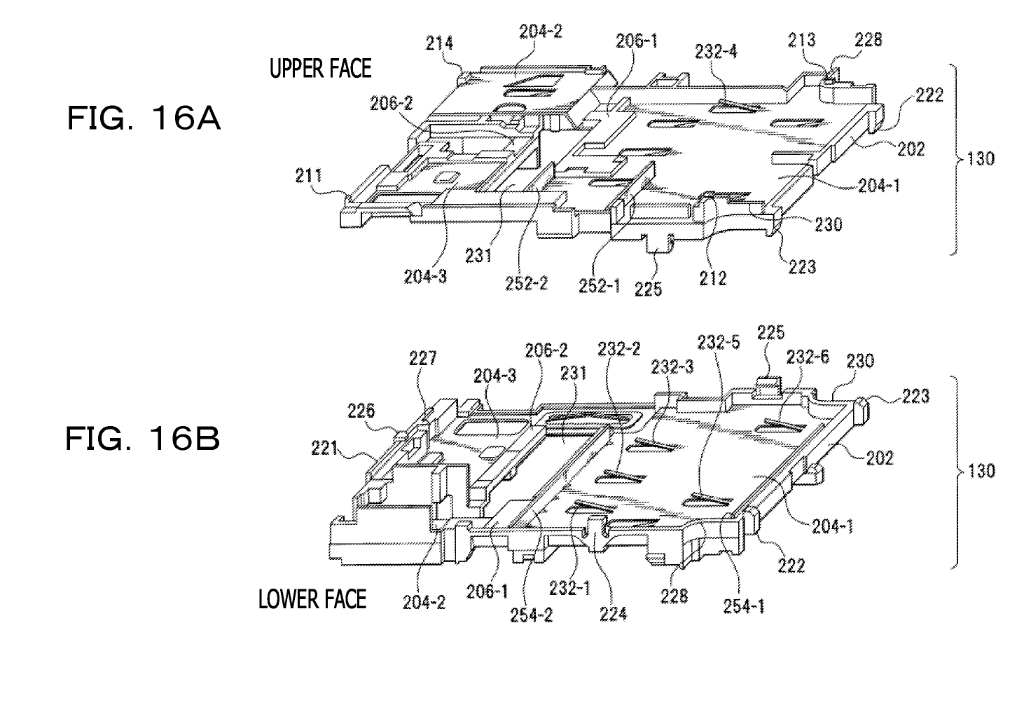

FIG. 16A illustrates an upper face of an inter-substrate frame, and FIG. 16B illustrates a lower face of the inter-substrate frame.

The inter-substrate frame 130 depicted in FIG. 16A includes a frame portion 202, shield frames 204-1, 204-2, and 204-3, and reinforcing frames 206-1 and 206-2. The shield frames 204-1, 204-2, and 204-3 are arranged in the inner side of the frame portion 202 and are fixed on the frame portion 202. The reinforcing frames 206-1 and 206-2 couple the frame portion 202 and the shield frames 204-1, 204-2, and 204-3 so as to reinforce the inter-substrate frame 130. The frame portion 202, the shield frames 204-1, 204-2, and 204-3, and the reinforcing frames 206-1 and 206-2 are coupled with each other.

The frame portion 202 and the reinforcing frames 206-1 and 206-2 are made of resin, for example. The substrate 12 is brought into contact with an edge face of the upper side of the frame portion 202. The substrate 22 is brought into contact with an edge face of the lower side of the frame portion 202. The substrate 12 and the substrate 22 are arranged with a predetermined gap interposed therebetween due to the frame portion 202. A space for arranging electronic members is secured by the inter-substrate frame 130.

On the edge portion of the upper side of the frame portion 202, a plurality of protruded portions 211, 212, 213, and 214 are formed. These protruded portions 211, 212, 213, and 214 correspond to the edge portion of the substrate 12 and suppress movement of the substrate 12. On the edge portion of the lower side of the frame portion 202, a plurality of protruded portions 221, 222, and 223 and a plurality of claws 224 and 225 are formed. These protruded portions 221, 222, and 223 and claws 224 and 225 correspond to the edge portion of the substrate 22 and suppress movement of the substrate 22. Further, on the protruded portion 221, an overhang portion 226 and a projected portion 227 are formed. This overhang portion 226 suppresses separation of the substrate 22 from the lower face of the frame portion 202, together with the claws 224 and 225. The projected portion 227 is used for joining between the substrate 22 and the inter-substrate frame 130.

An opening 231 is formed on the frame portion 202, facilitating coupling between the male connector portion 34 and the female connector portion 36. Further, in the frame portion 202, positions of the frame retreat at retreat portions 228 and 230.

The shield frames 204-1, 204-2, and 204-3 are made of a metal material such as metal plates, for example. On the shield frame 204-1, a plurality of tongue piece portions 232-1, 232-2, . . . , 232-6 are formed.

The tongue piece portions 232-1, 232-2, . . . , 232-6 are formed by cutting out the metal material on the outer side of the tongue piece portions 232-1, 232-2, . . . , 232-6, for example. Alternatively, the tongue piece portions 232-1, 232-2, . . . , 232-6 may be formed by cutting in the outer circumference of the tongue piece portions 232-1, 232-2, . . . , 232-6, for example.

The tongue piece portion 232-4 is bent toward the upper side. Accordingly, the tongue piece portion 232-4 is brought into contact with the access device 138 (FIG. 12B). The surface of the access device 138 is made of a metal material, for example, and the ground of the substrate 12 is strengthened by the contact with the tongue piece portion 232-4.

The tongue piece portions 232-1, 232-2, 232-3, 232-5, and 232-6 are bent toward the lower side to be brought into contact with the shield cap 128 (FIG. 11). Contact between the tongue piece portions 232-1, 232-2, 232-3, 232-5, and 232-6 and the shield cap 128 strengthens the ground of the substrate 22.

The wall portions 252-1 and 252-2 are formed on the upper face of the shield frame 204-1 and the wall portions 254-1 and 254-2 are formed on the lower face of the shield frame 204-1. The wall portions 252-1, 252-2, 254-1, and 254-2 are formed by processing the shield frame 204-1. For example, the wall portions 252-1, 252-2, 254-1, and 254-2 are formed by bending the shield frame 204-1. When the shield frame 204-1 is bent, the shield frame 204-1 may be further folded back. Accordingly, the shield frame 204-1 becomes double, raising strength of the wall portions 252-1, 252-2, 254-1, and 254-2. In addition to such processing of the shield frame 204-1, when the wall portions are made of the metal material, hardness of the wall portions is raised.

The wall portions 252-1, 252-2, 254-1, and 254-2 may be formed by adding beams to the shield frame 204-1. Between the wall portions 252-1 and 252-2, the shield cap 126 (FIG. 11) is fitted. Between the wall portions 254-1 and 254-2, the shield cap 128 (FIG. 11) is fitted.

<Disposition of Shield Cap 128>

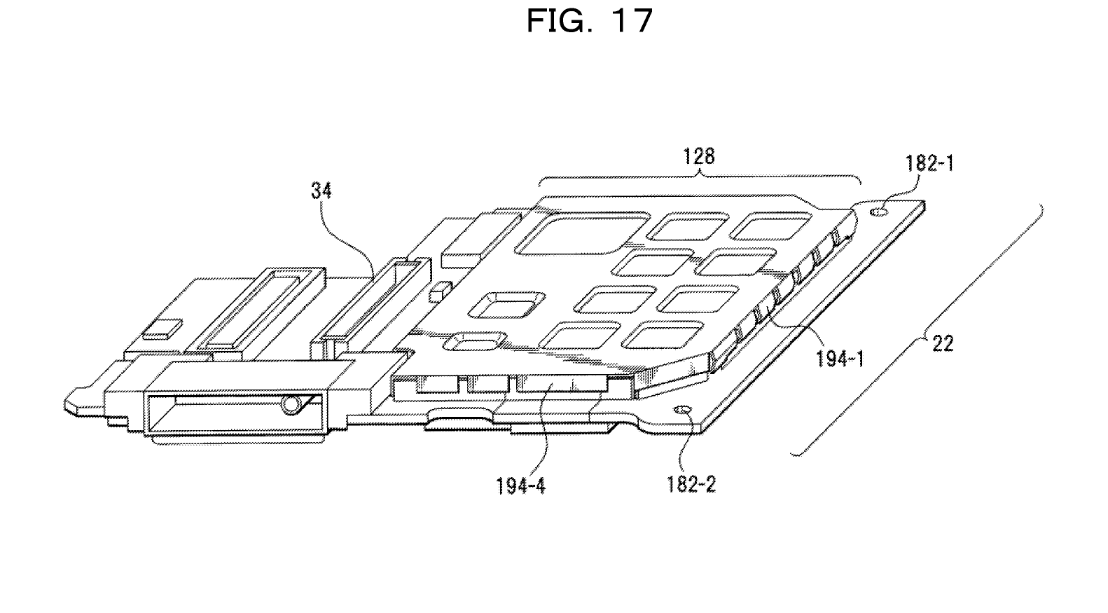

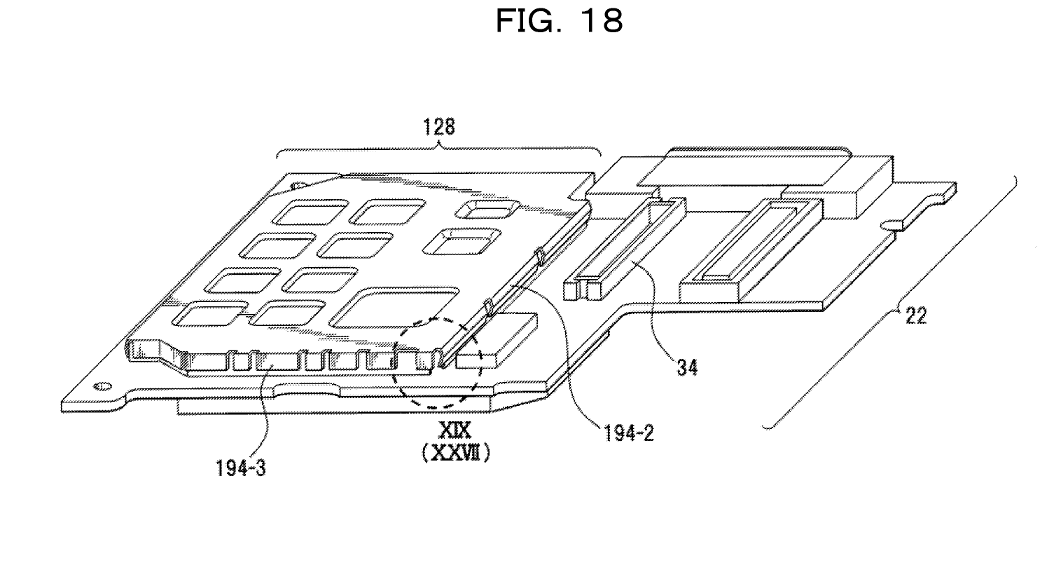

FIG. 17 and FIG. 18 illustrate a substrate on which a shield cap is disposed. In a state that the shield cap 128 is disposed on the substrate 22, the male connector portion 34, the leg portion 194-1, and the leg portion 194-2 are arranged in a longitudinal direction of the mobile telephone 102. Accordingly, the shield cap 128 has elasticity in the longitudinal direction of the mobile telephone 102.

<Configuration of Leg Portion>

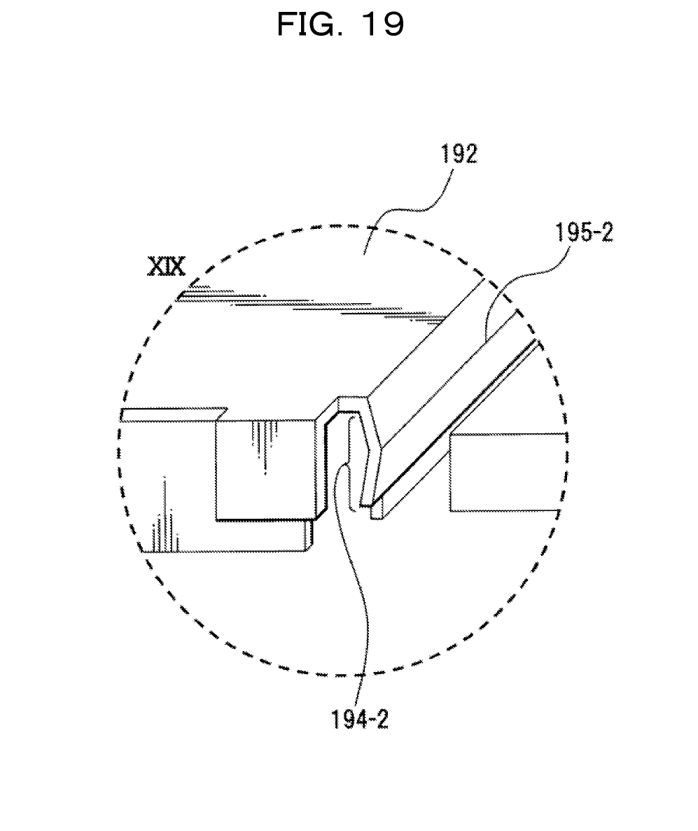

FIG. 19 illustrates an edge portion of a shield cap in a manner to enlarge the range XIX depicted in FIG. 18. The leg portion 194-2 depicted in FIG. 19 is composed of a bent portion 195-2 and two tilt portions. The bent portion 195-2 is formed on a central part of the leg portion 194-2. The first tilt portion is tilted from the edge of the lid portion 192 to the bent portion 195-2 in the more outward direction than the lid portion 192. The second tilt portion is tilted from the bent portion 195-2 to an edge portion of the leg portion 194-2 in the inward direction of the lid portion 192. In a similar manner, the leg portion 194-1 depicted in FIG. 17 is bent and the leg portions 164-1 and 164-2 of the shield cap 126 (FIGS. 13A and 13B) disposed on the substrate 12 are bent.

<Engagement Between Substrate 12 and Inter-Substrate Frame 130>

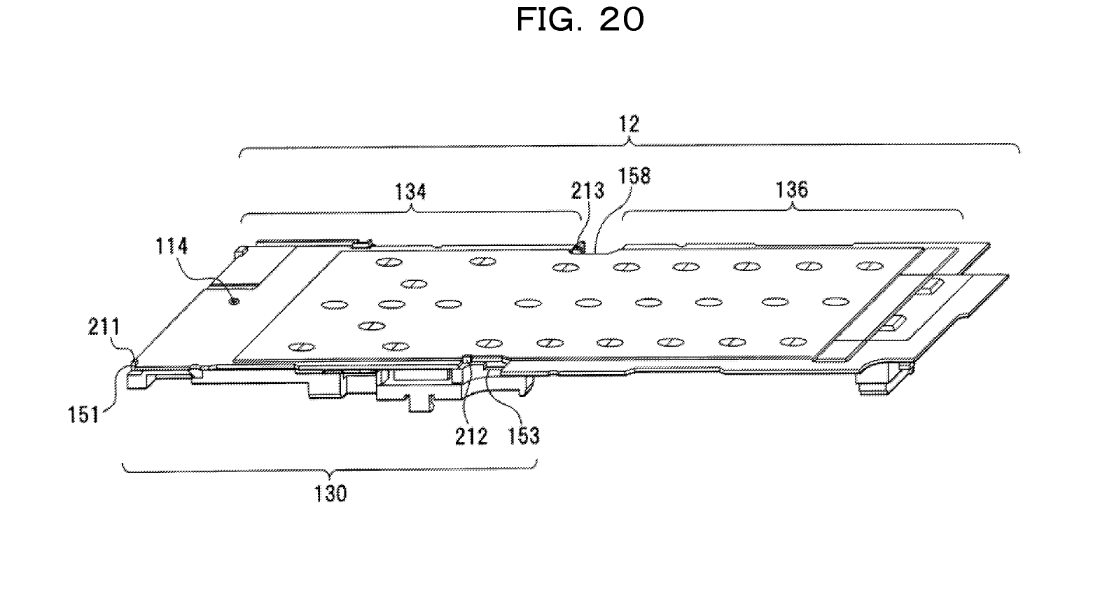

FIG. 20 illustrates engagement between a substrate and an inter-substrate frame. The electronic member arrangement region 134 of the substrate 12 is engaged with the upper face of the inter-substrate frame 130. In this engaging state, the protruded portion 211 of the inter-substrate frame 130 is adjacent to the concave portion 151 at a corner of the substrate 12. The protruded portion 212 of the inter-substrate frame 130 is adjacent to a corner of the bottom of the concave portion 153 of the substrate 12 on the protruded portion 211 side. The protruded portion 213 is adjacent to a corner of the bottom of the concave portion 158 on the protruded portion 211 side. The concave portion 153 and the concave portion 158 are provided on opposed edge faces of the substrate 12. Thus, the protruded portions 211, 212, and 213 hold the substrate 12 at three points.

For the engagement between the substrate 12 and the inter-substrate frame 130, a room (backlash) is set. This room secures predetermined movement freedom between the substrate 12 and the inter-substrate frame 130. Accordingly, an operation for assembling the substrate 12, the inter-substrate frame 130, and the substrate 22 is facilitated. Further, it is possible to secure a difference among the substrates 12 and 22 and the inter-substrate frame 130, such as a maximum value of a permitted dimensional error.

<Engagement Between Substrate 22 and Inter-Substrate Frame 130>

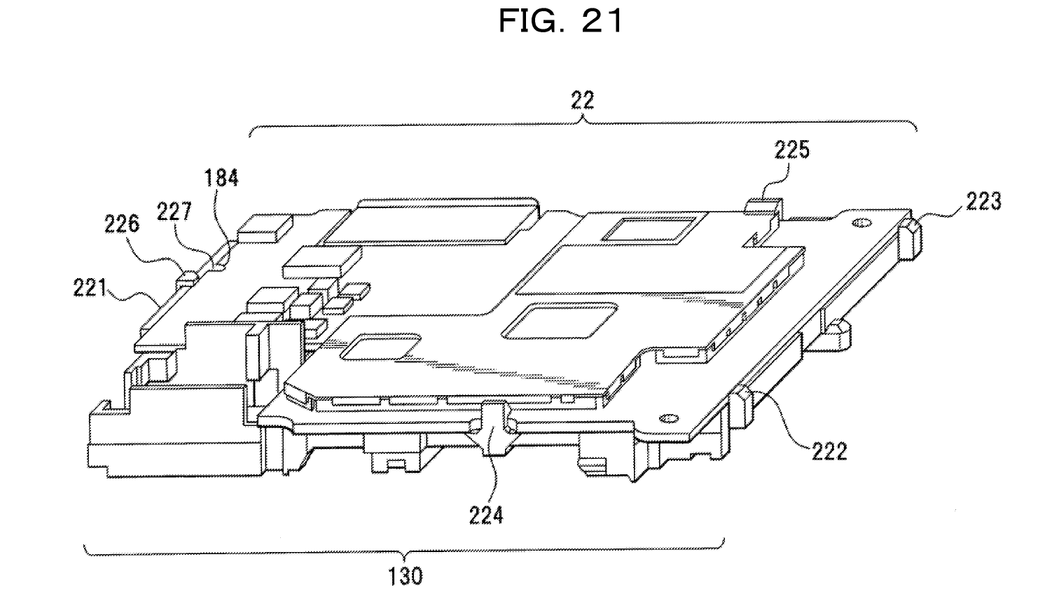

FIG. 21 illustrates engagement between a substrate and an inter-substrate frame. The substrate 22 is engaged with the lower face of the inter-substrate frame 130. In this engaging state, the protruded portions 222 and 223 of the inter-substrate frame 130 are adjacent to one edge face of the substrate 22. Further, the protruded portion 221, the claw 224, and the claw 225 are respectively adjacent to three edge faces which are different from the edge face to which the protruded portions 222 and 223 are adjacent. Thus, the protruded portions 221, 222, and 223 and the claws 224 and 225 hold four edge faces of the substrate 22. Further, the projected portion 227 of the inter-substrate frame 130 and the cutout portion 184 of the substrate 22 are joined to each other, strengthening engagement between the substrate 22 and the inter-substrate frame 130.

For the engagement between the substrate 22 and the inter-substrate frame 130, a room (backlash) is set. This room secures predetermined movement freedom between the substrate 22 and the inter-substrate frame 130. Accordingly, an operation for assembling the substrate 12, the inter-substrate frame 130, and the substrate 22 is facilitated. Further, it is possible to secure difference among the substrates 12 and 22 and the inter-substrate frame 130.

<Attachment of Substrates 12 and 22 and Inter-Substrate Frame 130>

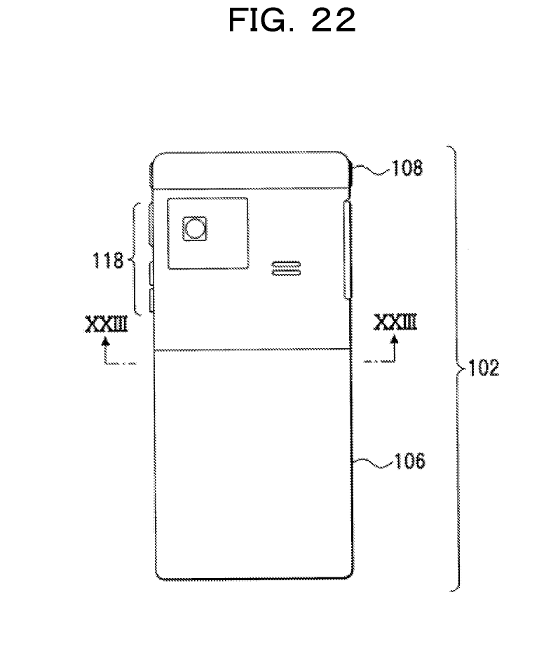

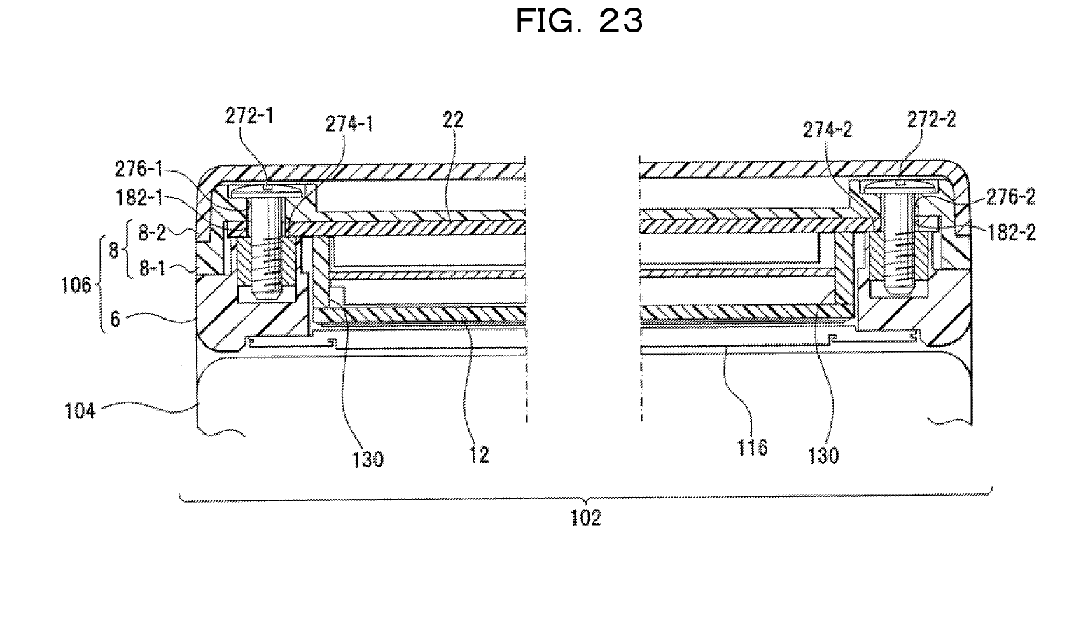

FIG. 22 illustrates a back face of a mobile telephone. FIG. 23 is a sectional view, which is taken along a XXIII-XXIII line of FIG. 22, of a part of the mobile telephone depicted in FIG. 22. Here, regarding a sectional face of the movable casing portion 104, FIG. 23 illustrates only an outer shape of the movable casing portion 104.

In the mobile telephone 102 depicted in FIG. 23, the through hole 182-1 of the substrate 22 and the through hole 276-1 of the case body portion 8-1 are superposed oversuperposed over the screw receiving portion 274-1 of the upper case 6. Then, the axis portion of the fixing screw 272-1 is inserted through the through hole 182-1 and the through hole 276-1 so as to be screwed into the screw receiving portion 274-1. Further, the through hole 182-2 of the substrate 22 and the through hole 276-2 of the case body portion 8-1 are superposed over the screw receiving portion 274-2 of the upper case 6. Then, the axis portion of the fixing screw 272-2 is inserted through the through hole 182-2 and the through hole 276-2 so as to be screwed into the screw receiving portion 274-2. Thus, the substrate 22 and the case body portion 8-1 are fixed on the upper case 6 by the fixing screws 272-1 and 272-2.

The substrate 12 is separated from the screw receiving portions 274-1 and 274-2 due to the concave portions 158 and 153 (FIGS. 12A and 12B). Further, the inter-substrate frame 130 is separated from the screw receiving portions 274-1 and 274-2 by the retreat portions 228 and 230 (FIGS. 16A and 16B). Accordingly, the substrate 12 and the inter-substrate frame 130 are attached on the fixed casing portion 106 through the coupling with the substrate 22.

<Coupling Between Substrate 12 and Substrate 22>

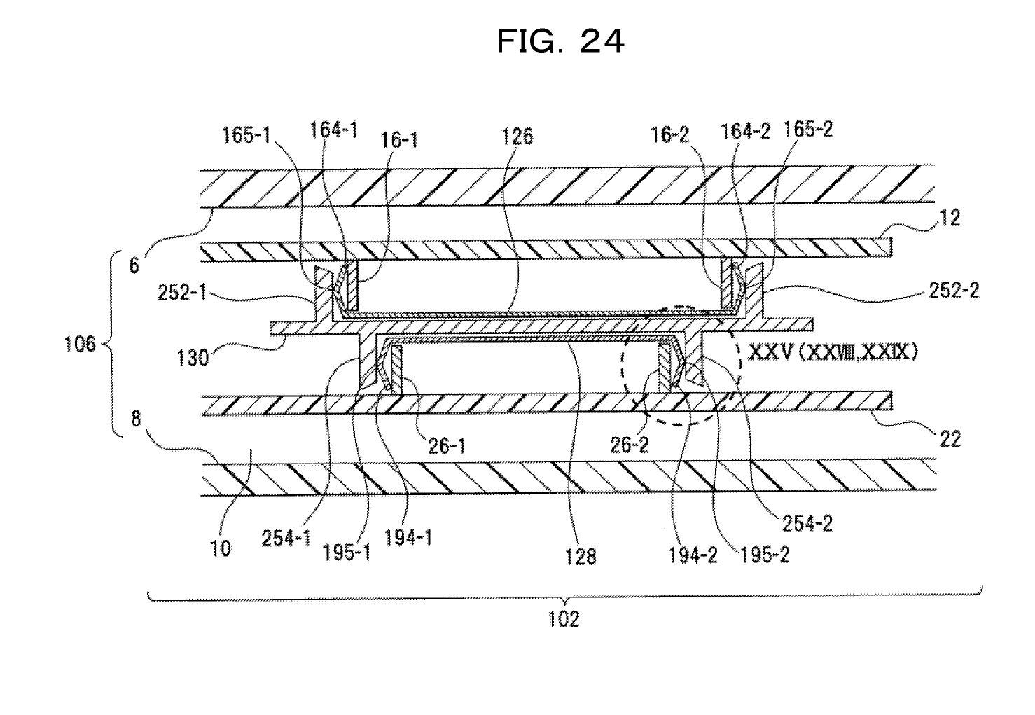

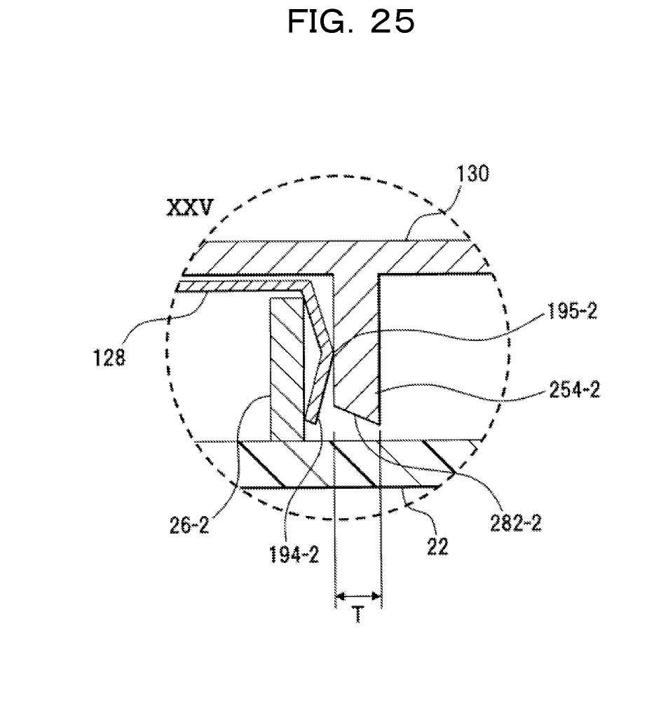

FIG. 24 is a sectional view of a part of a mobile telephone. FIG. 25 illustrates a leg portion and a wall portion in an enlarging manner. FIG. 25 illustrates a range XXV depicted in FIG. 24 in an enlarging manner.

The female connector portion 36 of the connector 32 and the frame members 16-1 and 16-2 are disposed on the opposed face portion, which is opposed to the substrate 22, of the substrate 12 which is disposed on the upper case 6 side. On the substrate 12, a plurality of electronic components which are not depicted are mounted.

Further, the male connector portion 34 of the connector 32 and the frame members 26-1 and 26-2 are disposed on the opposed face portion, which is opposed to the substrate 12, of the substrate 22 which is disposed on the lower case 8 side. On the substrate 22, a plurality of electronic components which are not depicted are mounted.

The frame members 16-1 and 16-2 are examples of a wall member, and are disposed on the substrate 12 to form walls. These frame members 16-1 and 16-2 are covered by the shield cap 126. This shield cap 126 is an example of a shield member and is made of a metal material, for example. The shield cap 126 is held on the frame members 16-1 and 16-2 by elasticity of this metal material. In a similar manner, the frame members 26-1 and 26-2 are examples of a wall member, and are disposed on the substrate 22 to form walls. These frame members 26-1 and 26-2 are covered by the shield cap 128. This shield cap 128 is an example of a shield member and is made of a metal material, for example. The shield cap 128 is held on the frame members 26-1 and 26-2 by elasticity of this metal material.

The inter-substrate frame 130 is interposed between the substrates 12 and 22. That is, this inter-substrate frame 130 is interposed between the shield caps 126 and 128. On this inter-substrate frame 130, the wall portions 252-1 and 252-2 are formed in a manner to sandwich the shield cap 126. The wall portion 252-1 faces the leg portion 164-1 of the shield cap 126 and the frame member 16-1 and the wall portion 252-2 faces the leg portion 164-2 of the shield cap 126 and the frame member 16-2. Further, the wall portions 254-1 and 254-2 are formed on the inter-substrate frame 130 in a manner to sandwich the shield cap 128. The wall portion 254-1 faces the leg portion 194-1 of the shield cap 128 and the frame member 26-1 and the wall portion 254-2 faces the leg portion 194-2 of the shield cap 128 and the frame member 26-2.

On the female connector portion 36, the male connector portion 34 is attached. This connector 32 connects the substrate 12 and the substrate 22 with each other. That is, the connector 32 is used for connection of the electronic circuit on the substrate 12 and the electronic circuit of the substrate 22 and is used for mechanical connection between the substrates 12 and 22.

The leg portions 164-1 and 164-2 of the shield cap 126 are bent at bent portions 165-1 and 165-2 and have elasticity. Therefore, the shield cap 126 is fitted on the inter-substrate frame 130. In a similar manner, the leg portions 194-1 and 194-2 of the shield cap 128 are bent at bent portions 195-1 and 195-2 and have elasticity. Therefore, the shield cap 128 is fitted on the inter-substrate frame 130. As a result, connection among the substrates 12 and 22 and the inter-substrate frame 130 is strengthened, being able to strengthen the grounds of the substrates 12 and 22 and enhance heat discharge of electronic members in an operation of circuits.

As depicted in FIG. 25, an expansion tilt face portion 282-2 is formed on the wall portion 254-2 on the end part of the wall portion 254-2 and on an arrangement side of the leg portion 194-2. Due to this expansion tilt face portion 282-2, the thickness T of the wall portion 254-2 is decreased toward the end part and thus, the end part of the wall portion 254-2 is pointed. This expansion tilt face portion 282-2 guides insertion of the leg portion 194-2 when the substrate 22 is attached to the inter-substrate frame 130. The tilt of the end part of the wall portion 254-2 facilitates assembling between the substrate 22 and the inter-substrate frame 130. In a similar manner, expansion tilt face portions are formed on the wall portions 252-1, 252-2, and 254-1. The tilt of the end part of each of the wall portions 252-1, 252-2, and 254-1 facilitates assembling of the substrates 12 and 22 and the inter-substrate frame 130.

<Motion in Impact Reception>

(1) Case in which Impact is Applied to Substrate 12

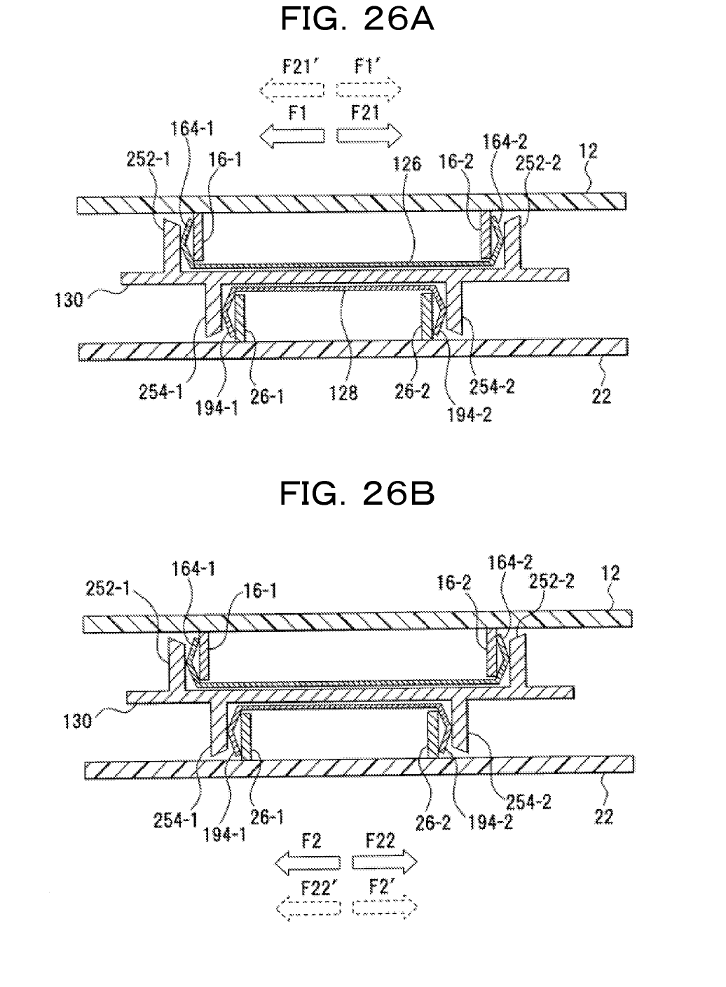

When an impact is applied to the substrate 12, displacement is generated between the substrate 12 and the substrate 22. In this case, the frame members 16-1, 16-2, 26-1, and 26-2 lock the wall portions 252-1, 252-2, 254-1, and 254-2 of the inter-substrate frame 130 in response to the generated displacement. For example, when an impact F1 is applied to the substrate 12 as depicted in FIG. 26A, repulsion force F21 is generated due to the lock between the frame member 16-1 and the wall portion 252-1, the lock between the frame member 26-2 and the wall portion 254-1, and elasticity of the leg portions 164-1 and 194-2, reducing the impact F1. The impact F1 is dispersed and absorbed by the leg portions 164-1 and 194-2 and the frame members 16-1 and 26-2. As a result, the impact, which exists between the substrates 12 and 22, with respect to the connector 32 is reduced, being able to suppress stress which is applied to the connecting portion of the connector 32. In a similar manner, when an impact F1′ is applied to the substrate 12, repulsion force F21′ is generated due to the lock between the frame member 16-2 and the wall portion 252-2, the lock between the frame member 26-1 and the wall portion 254-1, and elasticity of the leg portions 164-2 and 194-1, reducing the impact F1′.

(2) Case in which Impact is Applied to Substrate 22

When an impact is applied to the substrate 22, displacement is generated between the substrate 12 and the substrate 22. In this case, the frame members 16-1, 16-2, 26-1, and 26-2 lock the wall portions 252-1, 252-2, 254-1, and 254-2 of the inter-substrate frame 130 in response to the generated displacement. For example, when an impact F2 is applied to the substrate 22 as depicted in FIG. 26B, repulsion force F22 is generated due to the lock between the frame member 16-2 and the wall portion 252-2, the lock between the frame member 26-1 and the wall portion 254-1, and elasticity of the leg portions 164-2 and 194-1, reducing the impact F2. The impact F2 is dispersed and absorbed by the leg portions 164-2 and 194-1 and the frame members 16-2 and 26-1. As a result, the impact, which exists between the substrates 12 and 22, with respect to the connector 32 is reduced, being able to suppress stress which is applied to the connecting portion of the connector 32. In a similar manner, when an impact F2′ is applied to the substrate 22, repulsion force F22′ is generated due to the lock between the frame member 16-1 and the wall portion 252-1, the lock between the frame member 26-2 and the wall portion 254-2, and elasticity of the leg portions 164-1 and 194-2, reducing the impact F2′.

<Method for Manufacturing Mobile Terminal Device 2>

For the manufacturing of the mobile telephone 102, the same process as that of the first embodiment may be used. In this case, an edge of a material which is to be a shield cap through a press wok or the like may be bent or folded to form a leg portion in the manufacturing of the shield caps 126 and 128. Further, in the manufacturing of the inter-substrate frame 130, the expansion tilt face portion 282-2 is formed on the wall portions 252-1, 252-2, 254-1, and 254-2, realizing enhancement of the assembling property of the mobile telephone 102.

Modification examples of the second embodiment are described below.

The leg portions 164-1, 164-2, 194-1, and 194-2 are bent at the central parts thereof, but the bent parts are not limited to the central parts.

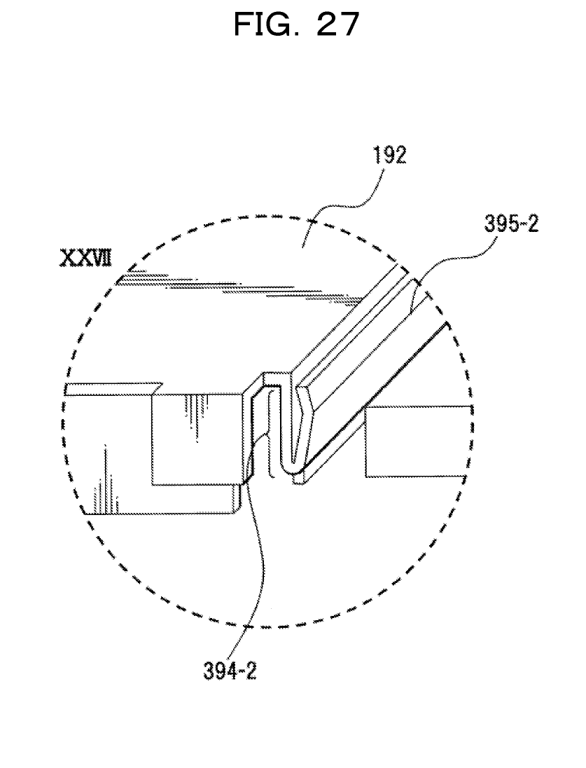

FIG. 27 illustrates another example of a leg portion and another example of the range XXVII (FIG. 18). A leg portion 394-2 depicted in FIG. 27 is folded back toward the outside at the central part thereof. A portion which is folded back toward the outside is composed of a bent portion 395-2 and two tilt portions. The bent portion 395-2 is formed on the central part of the leg portion which is folded back toward the outside. The first tilt portion is tilted in a manner to separate from the lid portion 192 from the central part of the leg portion 394-2 to the bent portion 395-2. The second tilt portion is tilted in a manner to approach the lid portion 192 from the bent portion 395-2 to the end part of the leg portion 394-2. This leg portion 394-2 may also have elasticity. In a similar manner, the leg portions 164-1, 164-2, and 194-1 may be formed to have shapes same as that of the leg portion 394-2.

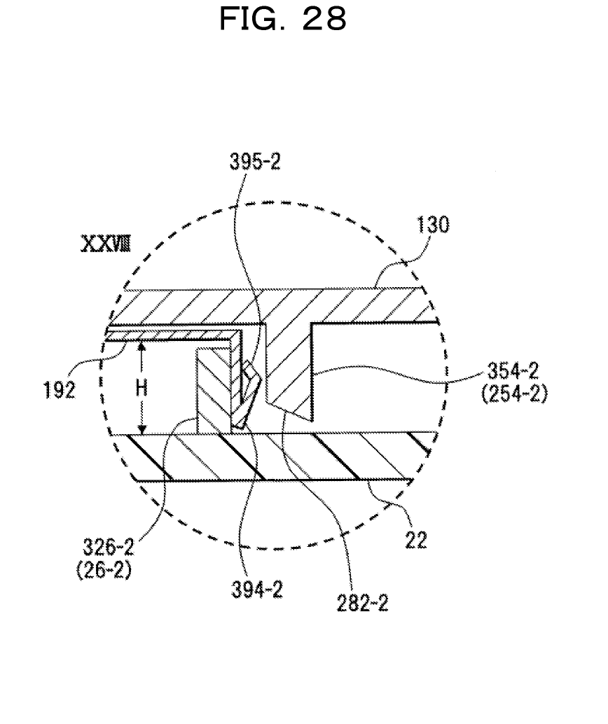

FIG. 28 illustrates another example of a wall portion and another example of the range XXVIII (FIG. 24). The leg portion 394-2 depicted in FIG. 28 is folded back toward the outside, being able to reduce the height H compared to the case in which the leg portion 394-2 is not folded back. Therefore, it is possible to set the frame member 326-2 lower than the frame member 26-2 (FIG. 25) and set the wall portion 354-2 lower than the wall portion 254-2 (FIG. 25). That is, it is possible to lower the height from the substrate 22 to the lid portion 192. Further, the leg portion 394-2 is brought into contact with the frame members 326-2 at faces thereof, being able to strengthen the lock between the shield cap and the frame member and the ground.

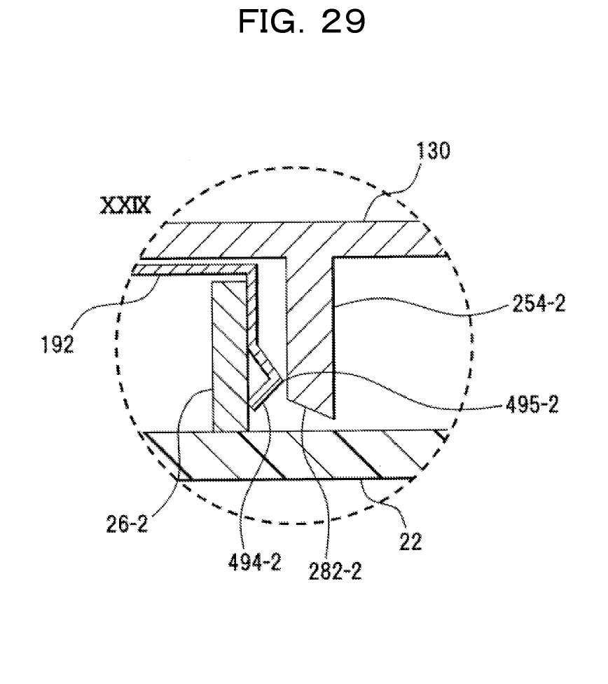

In a leg portion 494-2 depicted in FIG. 29, a bent portion 495-2 is formed on the lower part of the leg portion 494-2. This leg portion 494-2 may also have elasticity. Here, the leg portions 164-1, 164-2, and 194-1 may be formed to have shapes same as that of the leg portion 494-2.

### Comparison Example

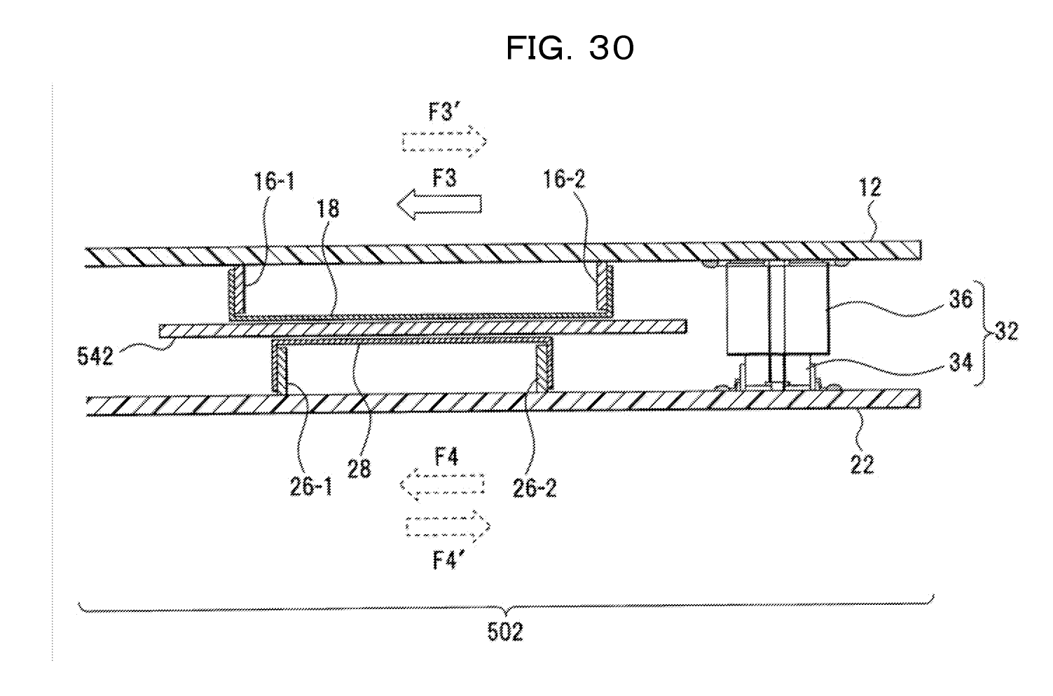

FIG. 30 illustrates a mobile telephone according to a comparison example. In a mobile telephone 502 depicted in FIG. 30, an inter-substrate frame 542 has a flat shape. When an impact F3 is applied to the substrate 12, the substrate 12 moves toward the direction of the impact F3 and the impact F3 concentrates on the connector 32. That is, the impact concentrates on one place. The same goes for a case in which an impact F3′ is applied to the substrate 12, a case in which an impact F4 is applied to the substrate 22, and a case in which an impact F4′ is applied to the substrate 22.

Features and modifications of the above-described embodiments are cited below.

(1) The example of the mobile terminal device and the mobile telephone has been described in the above embodiments. The electronic device and the method for manufacturing an electronic device according to embodiments of the present disclosure may be electronic devices which are assumed to receive an impact through falling or the like. For example, a smartphone, a computerized game console, a camera, a television receiver, a radio receiver, a navigation device, and the like may be employed.

(2) In the above embodiments, the example in which the wall portions are provided to the inter-substrate frame on both of the substrate 12 side and the substrate 22 side. The wall portion may be provided to either one side of the first substrate side and the second substrate side. In this case, the wall portion is capable of receiving an impact of the substrate 12 or the substrate 22. Further, a wall portion may be provided to either one of the substrate 12 side and the substrate 22 side and another unit may be combined. An impact is received by using an engaging unit as another unit such as a protrusion, a recess, and a claw between the substrate 12 or the substrate 22 and the inter-substrate frame. The combination with another unit enables dispersion of the impact on the substrate 12 and the substrate 22. Such configuration is also capable of reducing impact force which is applied to the connector. In a similar manner to the wall portion of the inter-substrate frame, the frame member may be provided to either one of the substrates 12 and 22 to absorb an impact or the like together with another unit. Such configuration is also capable of reducing impact force which is applied to the connector.

(3) The example in which the wall portions are provided on both of a side closer to the connector and a side distant from the connector has been described in the above embodiments. The wall portion may be either one of the side closer to the connector or the side distant from the connector. In this case, the wall portion is capable of receiving an impact of a specific direction which is applied to the substrate 12 or the substrate 22. Further, the wall portion may be provided either one of the sides and another unit may be combined. The combination with another unit enables dispersion of impacts of directions other than a specific direction. Such configuration is also capable of reducing impact force which is applied to the connector.

(4) The leg portion is bent to form a spring in the leg portion in the above-described embodiments. For example, an elastic material such as sponge and rubber may be bonded on the leg portion. Such configuration also realizes elasticity of the leg portion. Further, elasticity may be generated between the leg portion and the wall portion. For example, an elastic material may be bonded to the wall portion or an elastic material may be inserted between the leg portion and the wall portion.

(5) The example in which the wall portion is formed by applying shield frame processing of the inter-substrate frame has been described in the second embodiment. For example, the wall portion may be formed by a frame portion or a reinforcing frame of the inter-substrate frame. In this case, a frame portion or a reinforcing frame is formed in the outer vicinity of each leg portion. In such configuration, it is possible to form a wall portion on the inter-substrate frame. Here, in a case where a frame portion or a reinforcing frame is made of resin, it is possible to easily form a wall portion.

(6) The example in which the number of a plurality of substrates is two has been described in the above embodiments. The number of substrates may be three or more. When the number of substrates is three, a third substrate may be disposed on the lower side of the substrate 22 and the surfaces of the third substrate and the substrate 22 may be connected by a connector. In this case, the above-described embodiments may be realized by using the third substrate and the substrate 22. Here, the electronic device and the method for manufacturing an electronic device according to embodiment of the present disclosure include a case where part of substrates among three or more substrates is used.

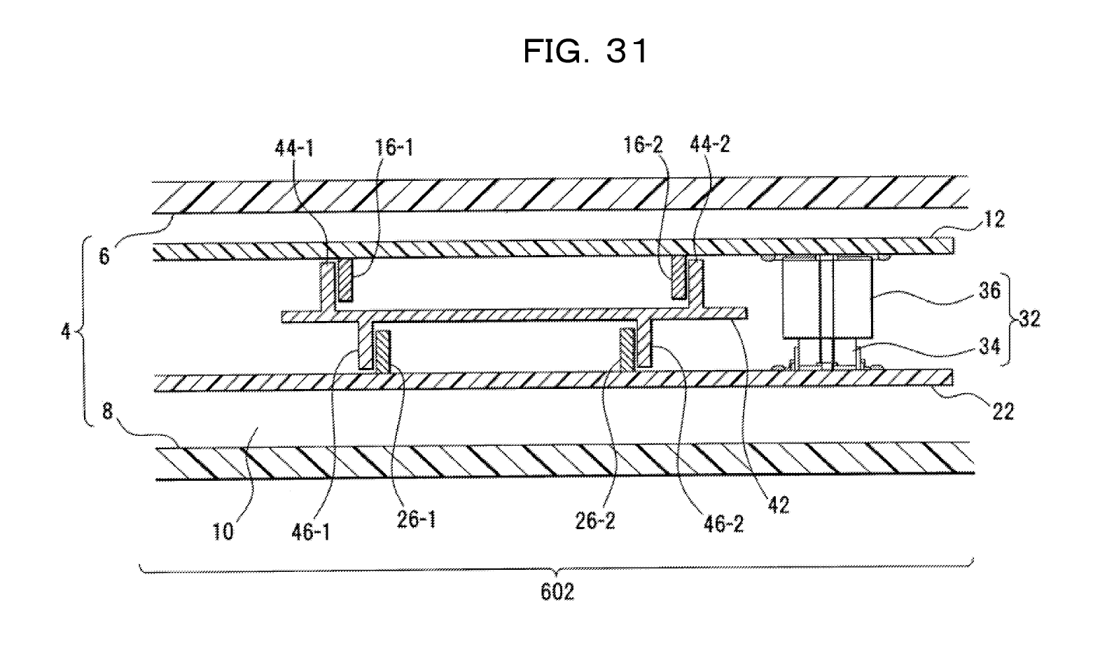

(7) The example in which the shield cap is provided has been described in the above embodiments, but embodiments of the present disclosure are not limited to this example. In a mobile terminal device 602 depicted in FIG. 31, the wall portion 44-1 and the frame member 16-1 are directly face each other. The wall portion 44-2 and the frame member 16-2 directly face each other. The wall portion 46-1 and the frame member 26-1 directly face each other. The wall portion 46-2 and the frame member 26-2 directly face each other. That is, no shield member is interposed.

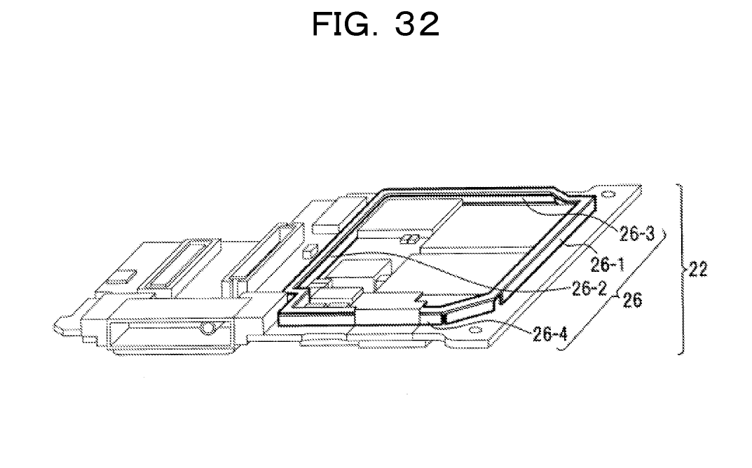

A substrate 22 depicted in FIG. 32 is an example of the substrate 22 according to the mobile terminal device 602. The substrate 22 includes the frame members 26-1, 26-2, 26-3, and 26-4, forming a frame 26 on the substrate 22. This frame 26 is disposed between the wall portions 46-1 and 46-2 of the inter-substrate frame 42, providing such configuration that the wall portions 46-1 and 46-2 directly face the frame members 26-1 and 26-2 respectively. In a similar manner, a frame including the frame members 16-1 and 16-2 is formed on the substrate 12 and this frame is disposed between the wall portions 44-1 and 44-2 of the inter-substrate frame 42, providing such configuration that the wall portions 44-1 and 44-2 directly face the frame members 16-1 and 16-2 respectively.

Due to the provision of such configuration, collision and lock between the wall portions 44-1, 44-2, 46-1, and 46-2 and the respectively-corresponding frame members 16-1, 16-2, 26-1, and 26-2 disperse and absorb an impact when the impact is applied to at least one of the substrate 12 and the substrate 22. As a result, an impact with respect to the connector 32 is reduced, being able to suppress stress which is applied to the connecting portion of the connector 32. The shapes of the frame members 26-1 and 26-2 are not limited to the shape of the frame 26 depicted in FIG. 32. For example, the frame members 26-1 and 26-2 may be formed as independent wall members respectively. The frame members 16-1 and 16-2 may also be formed as independent wall members respectively. Such configuration is capable of reducing an impact with respect to the connector 32 and suppressing stress which is applied to the connecting portion of the connector 32.

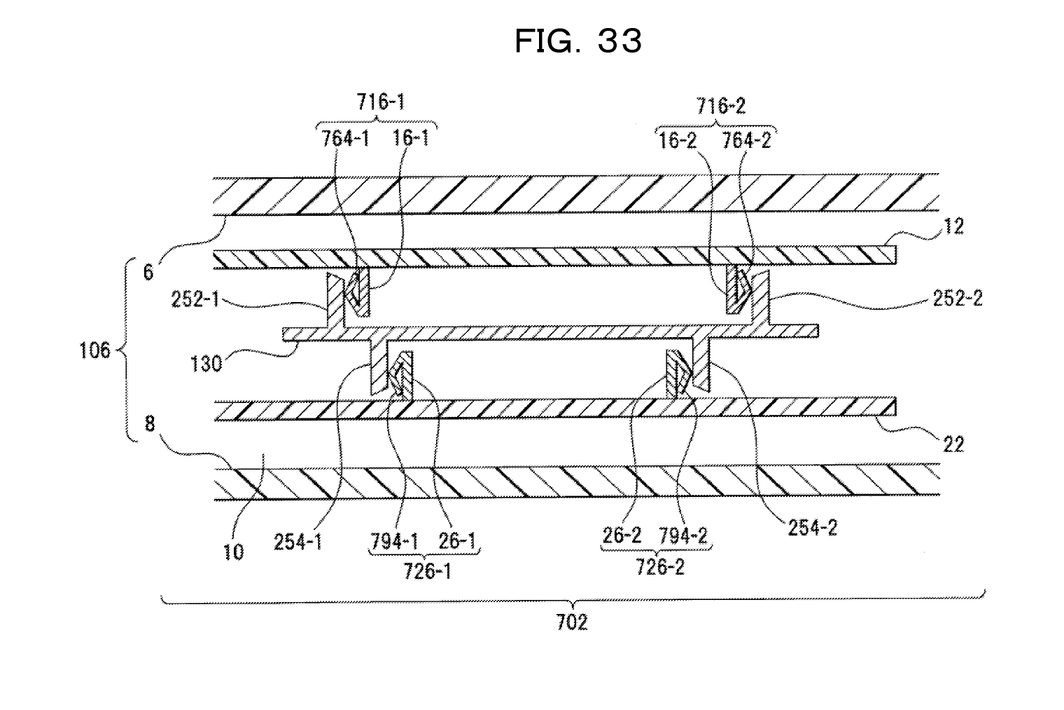

A mobile terminal device 702 depicted in FIG. 33 includes wall members 716-1, 716-2, 726-1, and 726-2. The wall member 716-1 includes the frame member 16-1 described above and an elastic member 764-1 which is connected with the frame member 16-1 and arranged between the frame member 16-1 and the wall portion 252-1. The wall member 716-2 includes the frame member 16-2 described above and an elastic member 764-2 which is connected with the frame member 16-2 and arranged between the frame member 16-2 and the wall portion 252-2. The wall member 726-1 includes the frame member 26-1 described above and an elastic member 794-1 which is connected with the frame member 26-1 and arranged between the frame member 26-1 and the wall portion 254-1. The wall member 726-2 includes the frame member 26-2 described above and an elastic member 794-2 which is connected with the frame member 26-2 and arranged between the frame member 26-2 and the wall portion 254-2. When an impact is applied to the substrates 12 and 22, the impact is dispersed and absorbed by collision and lock between the wall portions 252-1, 252-2, 254-1, 254-2 and respective wall members 716-1, 716-2, 726-1, and 726-2. The wall members 716-1, 716-2, 726-1, and 726-2 include the elastic members 764-1, 764-2, 794-1, and 794-2 respectively, so that the impact is further dispersed and absorbed. As a result, the impact with respect to the connector 32 is reduced, being able to suppress stress which is applied to the connecting portion of the connector 32. Here, the frame members 16-1 and 16-2 may be formed as independent members respectively and the frame members 26-1 and 26-2 may be formed as independent members respectively. That is, two wall members, for example, may be disposed instead of disposition of frames on substrates 12 and 22 respectively. Such configuration is also capable of reducing the impact with respect to the connector 32 and suppressing stress which is applied to the connecting portion of the connector 32. Here, in FIGS. 31, 32, and 33, elements same as those of the above-described embodiments are given the same reference characters and description thereof is omitted.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device, comprising:
a first substrate;
a second substrate that is disposed to be superposed over the first substrate;
a connector that connects the first substrate to the second substrate;
an inter-substrate frame that is disposed between the first substrate and the second substrate and includes a wall portion; and
a wall member that is disposed on at least one of the first substrate and the second substrate to be opposed to the wall portion and locks the wall portion of the inter-substrate frame in response to displacement that is generated between the first substrate and the second substrate.

2. The electronic device according to claim 1, wherein the wall portion of the inter-substrate frame is disposed on the inter-substrate frame or is formed by bending the inter-substrate frame.

3. The electronic device according to claim 1, wherein the wall member includes an elastic member and has elasticity with respect to the wall portion of the inter-substrate frame.

4. The electronic device according to claim 1, wherein the wall member includes a bent portion, the bent portion having elasticity, on a contact portion contacting with the wall portion of the inter-substrate frame.

5. The electronic device according to claim 1, wherein the wall portion includes an expansion tilt face portion on an end side thereof.

6. A method for manufacturing an electronic device in which a first substrate and a second substrate, the first substrate and the second substrate being disposed to be superposed over each other, are connected by a connector, comprising:
forming a wall portion on an inter-substrate frame that is disposed between the first substrate and the second substrate;
disposing a wall member, the wall member being opposed to the wall portion and locking the wall portion of the inter-substrate frame in response to displacement that is generated between the first substrate and the second substrate, on either one of or each of the first substrate and the second substrate;
disposing the inter-substrate frame on the first substrate or the second substrate; and
connecting the first substrate and the second substrate with each other by a connector.

7. The method for manufacturing an electronic device according to claim 6, wherein the wall portion of the inter-substrate frame is disposed on the inter-substrate frame or is formed by bending the inter-substrate frame.

8. The method for manufacturing an electronic device according to claim 6, wherein an elastic member is formed on the wall member so that the wall member obtains elasticity with respect to the wall portion of the inter-substrate frame.

9. The method for manufacturing an electronic device according to claim 6, wherein a bent portion is formed on the wall member so as to provide elasticity to a contact portion between the wall member and the wall portion of the inter-substrate frame.

10. The method for manufacturing an electronic device according to claim 6, wherein an expansion tilt face portion is formed on an end side of the wall portion.
